(19) United States
(12) Patent Application Publication
(10) Pub. No.: US 2023/0223942 A1
(43) Pub. Date: Jul. 13, 2023

(54) Circuitry, System(s), and Method(s) to Automatically Align, Tune and Lock CDR Circuitry

(71) Applicant: Sean Iwasaki, Chicago, IL (US)

(72) Inventor: Sean Iwasaki, Chicago, IL (US)

(21) Appl. No.: 18/096,437

(22) Filed: Jan. 12, 2023

Related U.S. Application Data
(60) Provisional application No. 63/298,697, filed on Jan. 12, 2022.

(51) Int. Cl. H03L 7/08

(52) U.S. Cl. CPC H03L 7/0807

(57) ABSTRACT

The present subject matter relates to methods, systems, circuitry, equipment and devices providing for the automatic provisioning of clock data recovery (CDR) circuitry to automatically align, tune and lock the CDR circuitry to a communication signal. The methods, systems, circuitry, equipment and devices comprise a first CDR circuitry and a second CDR circuitry, and a first connection having two paths and a second connection having two paths. The CDR circuitry is automatically aligned kind locked a communication signal bit rate or wavelength or both. Automatic alignment is achieved by progressing through a communication services list until a communication signal bit rate or wavelength is aligned.

### RELATED APPLICATION(S)

This application claims benefit to U.S. Provisional Application Ser. No. 63/298,697 entitled Circuitry, Devices(s), System(s), and Method(s) to Automatically Align and Lock CDR Circuitry, filed Jan. 12, 2023 the entire disclosure of which is herein incorporated by reference.

### BACKGROUND

Wireless 5G services, cloud computing, and streaming video applications are exponentially increasing, the demand for hi her transmission capacity on communication networks and their infrastructure. The ubiquitous demand for 10 Gigabit, 100 Gigabit, 400 Gigabit, and higher transmission speeds have introduced many challenges to the Service Providers and their wired, optical, and wireless network infrastructures. Central to these challenges are the reliable transport, delivery, and integrity of these 10 Gigabit, 100 Gigabit, 400 Gigabit, and higher transmission speed communication services. The Service Providers communication network, infrastructure, and operations are extremely complex and vast, supporting many different legacy, mature, mid new communication services. The Service Providers implement many different and unique 10 Gigabit, 100 Gigabit, 400 Gigabit, and higher speed communication services for transport within their complex network and for delivery to their customers. These high speed communication services are unique in their signal types, modulations, wavelengths, symbol, and bit rates, and framing structures. Each unique framing structure reflects specific framing formats, payload encapsulation and data capacity. In addition, these unique 10 Gigabit, 100 Gigabit, 400 Gigabit, and higher speed communication services have different methods of operations, maintenance, and administration.

The 10 Gigabit, 100 Gigabit, 400 Gigabit, and higher speed communication services are also subjected to severe performance degradation, intermittent interoperability, and poor reliability. Most importantly, the Service Providers lace very complex installation, maintenance, and repair, which are subjected to installation and maintenance errors and repair delays. The Service Providers face costly decline in revenue, excessive expenses, and customer dissatisfaction. To address the Service Provider's issues on performance and reliability challenges, communication equipment use clock data recovery (CDR) circuitry to interface these high speed communication signals. The CDR circuitry extracts or creates a clock from the communication signal. This retimed clock will then be used to regenerate or recreate the communication signal to correct signal and timing impairments. This re-clocked and regenerated communication signal will be used by the communication equipment to reliably process the communication signal for connection and interlace to the network.

To address the various unique signals and structures of 10 Gigabit and higher communication services supported by the Service Providers, the communication equipment is required to specifically provision the CDR circuitry to align and lock each unique communication service bit rates or wavelengths, extract the clock, and re-clock the incoming communication signal. The CDR circuitry is typically pre-provisioned and involves manual or semi-automatic provisioning. Prior attempts to do so have thus far been inadequate.

One such example of prior art circuitry 100 is illustrated in the diagram of FIG. 1 (Prior Art) which depicts a clock data recovery circuitry (CDR) 110. The CDR 110 interfaces the communication signal through printed circuit board (PCB) trace connection 120. The CDR 110 aligns and, re-clocks the communication signal to other circuitry through PCB trace connections 122. The CDR 110 is connected to microprocessor 112 through PCB trace connections 124.

There are a number of disadvantages to the prior art circuitry 100 as shown in FIG. 1 (Prior Art). First, this prior art circuitry 100 can only align to a specific communication signal bit rate. The microprocessor 112 must provision the CDR 110 with specific communication service bit rate settings. These communication service bit rate settings provide the CDR 110 information to accurately and quickly align to the bit rate of the communication signal from PCB trace connections 120. If the prior art circuitry 100 receives a different communication signal bit rate from PCB trace connections 120, the CDR 110 will not align and re-clock the communication signal. For example, if the prior art circuitry 100 is provisioned to align to communication services with a bit rate of 10G LAN Ethernet (10.31250 (Gb/s) communication, the prior art circuitry 100 will not be able to align to a different communication service bit rate such as 10G WAN Ethernet (9.9528 Gb/s), Prior art circuitry 100 is used typically in consumer and some commercial Ethernet switches, routers, or other similar communication equipment.

A second such example of prior art circuitry 102 is illustrated in the diagram of FIG. 2 (Prior Art) which depicts the manual provisioning of the prior art circuitry 102. The prior an circuitry 102 is shown via call out arrow 130 as circuitry designed into a main board printed circuit board (PCB) assembly 152 of communication equipment 150. The prior art circuitry 102 is comprised of a CDR 110 connected to a microprocessor 112 through printed circuit board (PCB) trace connections 124. The microprocessor 112 provisions and controls the CDR 110 to align with a communication signal bit rate from connection 120. The microprocessor 112 is connected to user interface circuitry 114 through printed circuit board (PCB) trace connections 126. The CDR 110 will lock and extract the clock from the communication signal bit rate from connection 120 and transmit the re-clocked communication signal to connection 122. Connection 120 receives the communication signal from the main board PCB assembly 152. The main board PCB assembly 152 of communication equipment 150 performs optical-to-electrical signal conversion of the optical communication signal 180 from the equipment port connector 156 through a fiber cable 162 connected to a service provider's communication equipment 172. Connection 122 interfaces the main board PCB assembly 152 circuitry to transmit the re-clocked communication signal. The main board PCB assembly 152 of communication equipment 150 receives the re-clocked communication signal and performs electrical-to-optical signal and format conversion for transport of the optical communication signal 182 to the Customer's communication equipment 174 through fiber cable 164 connected to the equipment port 158 of communication equipment 150. The user interface circuitry 114 is connected to the main board PCB assembly 152 for interlacing the user interface port 154. The user interface port 154 is connected to a laptop computer 170 through cable 160.

There are a number of disadvantages to the prior art circuitry 102 as shown in FIG. 2 (Prior Art). First, this prior art circuitry 102 must be manually configured by a laptop computer or similar device to align with different network communication services 180. A skilled technician or craft person is required to drive to the remote location and configure the prior art circuitry 102 by connecting the laptop computer 170 to the user interface port 154 using cable 160. The craft person must configure the communication equipment 150 by entering a series of high-level command entries with the laptop computer 170. These series of command line interlace entries must be performed on every communication equipment within the network and updated if there are any service changes. A data center or a large Service Provider's network might have hundreds or thousands of communication equipment to be provisioned and configured. Configuring communication service bit rates to the prior art circuitry 102 is laborious, prone to errors, costly, and time consuming. Prior art circuitry 102 is used typically in consumer and some commercial Ethernet switches, routers, or other similar communication equipment.

A third such example of prior art circuitry 104 is illustrated in the diagram of FIG. 3 (Prior Art) which depicts the coordinated provisioning of the prior art circuitry 104. The prior art circuitry 104 is shown via callout arrow 132 as circuitry designed into a main board printed circuit board (PCB) assembly 152 of communication equipment 150. The prior art circuitry 104 is comprised of a CDR 110 connected to a microprocessor 112 through printed circuit board (PCB) trace connections 124. The microprocessor 112 provisions and controls the CDR 110 to align with a communication signal bit rate from connection 120. The microprocessor 112 is connected to communication circuitry 116 through printed circuit board (PCB) trace connections 128. The CDR 110 will lock and extract the clock from the communication signal bit rate from connection 120 and transmit the re-clocked communication signal to connection 122. Connection 120 receives the communication signal from the main board PCB assembly 152. The main board PCB assembly 152 of communication equipment 150 performs optical-to-electrical signal conversion of the optical communication signal 184 from the equipment port connector 156 through a fiber cable 162 connected to a service provider's communication equipment 172. Connection 122 interfaces the main board PCB assembly 152 circuitry to transmit the re-clocked communication signal. The main board PCB assembly 152 of communication equipment 150 receives the re-clocked communication signal and performs electrical-to-optical signal conversion to the equipment port 158. The re-clocked optical communication signal 186 from the equipment port 158 is connected to the customer's communication equipment 174 through a fiber cable 164. The communication circuitry 116 is connected to the main board PCB assembly 152 for processing the communication signal link to provision the CDR 110. The service provider's communication equipment 172 inserts provisioning information into the communication signal 184 message link. The communication signal 184 message link will be used by the communication equipment 150 to provision the CDR 110 with the service provider's communication service bit rate.

There are a number of disadvantages to the prior art circuitry 104 as shown in FIG. 3 (Prior Art). First, this prior art circuitry 104 requires coordination between the communication equipment 150 with the prior art circuitry 104 and the service provider's communication equipment 172 to provision the CDR 110. The service provider's communication equipment 172 will insert a message link within the communication signal 184 to align the CDR 110 to the communication signal 184 bit rate. The service provider's communication equipment 172 must be updated to insert the message link into the communication signal 184. A skilled technician or craft person is required to configure the prior art circuitry 104 by connecting the laptop computer 170 to the service provider's communication equipment 172 using cable 166. The craft person must configure the service provider's communication equipment 172 by entering a series of high-level command entries with the laptop computer 170. These series of command line interface entries must be performed on every communication equipment within the network or when there is a change in the communication service. The end-customer and Service Provider's communication services are always changing, and managing these changes and updates is complex, time consuming, and prone to errors. Communication equipment 150 using prior art circuitry 104 is typically Service Provider's communication equipment.

A fourth such example of prior art circuitry 106 is illustrated in the diagram of FIG. 4 (Prior Art) which depicts the zero or minimal provisioning of the prior art circuitry 106. The prior art circuitry 106 is shown via callout arrow 134 as circuitry designed into a main board printed circuit board (PCB) assembly 152 of communication equipment 150. The prior art circuitry 106 is comprised of a CDR 110 connected to a microprocessor 112 through printed circuit board (PCB) trace connections 124. The microprocessor 112 provisions and controls the CDR 110 to align with a communication signal bit rate from connection 120. The microprocessor 112 is connected to communication circuitry 116 through printed circuit board (PCB) trace connections 128. The microprocessor 112 is also connected to the user interface circuitry 114 through printed circuit board (PCB) trace connections 126. The CDR 110 will lock and extract the clock from the communication signal bit rate from connection 120 and transmit the re-clocked communication signal to connection 122. Connection 120 receives the communication signal from the main board PCB assembly 152. The main board PCB assembly 152 of communication equipment 150 performs optical-to-electrical signal conversion of the optical communication signal 188 from the equipment port connector 156 through a fiber cable 162 connected to a service provider's communication equipment 172. Connection 122 interfaces the main board PCB assembly 152 circuitry to transmit the re-clocked communication signal. The main board PCB assembly 152 of communication equipment 150 receives the re-clocked communication signal and performs electrical-to-optical signal and format conversion for transport of the re-clocked optical communication signal 190 to the Customer's communication equipment 174 through fiber cable 164 connected to the equipment port 158. The user interface circuitry 114 is connected to the main board PCB assembly 152 for initiating the command to provision the CDR 110. The communication circuitry 116 is connected to the main board PCB assembly 152 for processing the communication signal link to provision the CDR 110. The craft person initiates the CDR provisioning by issuing a command on a handheld device 176. The handheld device 176 is connected to a management port 154 of the communication equipment 150 by means of a cable 160. The provisioning command will be inserted within the link of the communication signal 188. The service provider's communication equipment 172 will received and extract the provisioning command message embedded within the communication signal 188. The service provider's communication equipment 172 will then forward the command and response message 192 to the Service Provider's network management 194 through connection 168. The network management system 194 may be within the service provider's communication equipment 172 or equipment located elsewhere within the service provider's network. The network management system 194 will respond with provisioning information to the command and response message 192. The reply with the Service Provider's network management 194 inserts provisioning information into the communication signal 188 message link. The communication signal 188 message link will be used by the communication equipment 150 to provision the CDR 110 with the service provider's communication service bit rate.

There are a number of disadvantages to the prior art circuitry 106 as shown in FIG. 4 (Prior Art). First, this prior art circuitry 106 requires the user to travel to the location where the communication equipment 150 is installed to initiate the provisioning of the CDR 110. Another disadvantage is the additional design complexity and cost of the communication equipment 150 and the service provider's communication equipment 172 to extract and process the communication service 188 message. Another disadvantage is administration management and coordination to provision the CDR 110 with the correct settings. Service provisioning errors and mistakes can occur when coordinating the communication service. If the communication service has been change, communication service installations must be delayed until the network management system 194 and the service provider's communication equipment 172 are updated with the correct CDR 110 settings.

The following prior art references provide general background information regarding the circuitry, systems, and methods on the alignment of communication services, and each are herein incorporated by reference:

U.S. Pat. No. 6,570.915 B1 entitled DSL Auto Baud issued to Sweitzer, et al, on May 27, 2003.

U.S. Pat. No. 9,559,905 B2 entitled Type-C Retimer State Machine and a Protocol for Inband Control and Configuration issued to Chen, et al, on Dec. 24, 2014.

U.S. Pat. No. 9,160,405 B1 entitled Self-Tuning High Speed Transceiver for IC Wireline Channel issued to Vareljian, et al. on Oct. 13, 2015.

U.S. Pat. No. 9,858,234 B2 entitled System Transparent Retimer issued to Chen, et al. on Jan. 2, 2018.

Presently, there is a need to automatically align and lock the CDR circuitry to various communication service bit rates and/or wavelength without manual, remote, or coordinated provisioning, while overcoming the inadequacies and disadvantages of such prior art, The circuitry, system(s), method(s), equipment and/or devices disclosed herein fulfill such a need.

### SUMMARY

The present disclosure provides circuitry, system(s), method(s), equipment and/or devices for automatically aligning or tuning on a communication signal bit rate or wavelength or a combination of wavelength and bit rate. When the communication signal is aligned and/or tuned, the signal's timing is extracted or recovered to re-clock and regenerate the communication signal. This communication signal is then re-clocked to remove timing impairments and then regenerated to correct for any signal impairments. This re-clocked and regenerated signal will be used by other equipment circuitry to reliably and accurately process the communication signal for interfacing with other networks and communication equipment. The circuitry, system(s), method(s), equipment and/or devices of the present disclosure do not require any technical craft person to locally provision the circuitry to align with multiple communication signal bit rates, wavelengths, or both. The circuitry, system(s), method(s), equipment and/or devices of the present disclosure also do not require remote provisioning, network management administration, or communication equipment coordination to align with multiple communication signal bit rates and wavelengths. In addition, the circuitry, system(s), method(s), equipment and/or devices of the present disclosure also do not require the deconstructing and analyzing of the communication signal structure, framing encapsulation, communication protocol, or imbedded payload messages, links, or identification codes to assist in the alignment of multiple communication signal bit rates or wavelengths.

The circuitry, system(s), method(s), equipment and/or devices of the present disclosure will automatically align or tune and lock to the communication signal bit rate, wavelength, or both wavelength and bit rate to re-clock or re-time, and re-generate the communication signal by way of clock data recovery (CDR) and a microprocessor (MPU) circuitries. In another embodiment, the present disclosure will automatically align or tune and lock to the communication signal bit rate, wavelength, or both wavelength and hit rate to re-clock or re-time, and re-generate the communication signal by way of CDRs, an MPU, and receiver and transmitter circuitries.

In still another embodiment, the circuitry, system(s), method(s), equipment and/or devices of the present disclosure will automatically align or tune and lock to the communication signal bit rate, wavelength, or both wavelength and bit rate to re-clock or re-time the communication signal by way CDRs, an MPU, receiver and transmitter circuitries, and port (PORT) interfaces.

Numerous features and advantages of the circuitry, system(s), method(s), equipment and/or devices of the present disclosure include the following.

The circuitry, system(s), method(s), equipment and/or devices of the present disclosure automatically align and lock to a communication signal and re-clock the communication signal bit rate.

The circuitry, system(s), method(s), equipment and/or devices of the present disclosure automatically time to a communication signal wavelength,

The circuitry, system(s), method(s), equipment and/or devices of the present disclosure automatically tune to a communication signal wavelength and align and lock to as communication signal bit rate.

The circuitry, system(s), method(s), equipment and/or devices of the present disclosure automatically tune to a communication signal wavelength and align and lock to a communication signal bit rate, and then re-clock the communication signal.

The circuitry, system(s), method(s), equipment and/or devices of the present disclosure automatically tune to a communication wavelength, align and lock to a communication signal bit rate, and re-clock the communication signal with any different communication wavelength.

The circuitry, system(s), method(s), equipment and/or devices of the present disclosure will selectively provision at least a second CDR with a first CDR settings.

The circuitry, system(s), method(s), equipment and/or devices of the present disclosure will selectively provision at least a second port (PORT) interface with a first port (PORT) interface settings.

The circuitry, system(s), method(s), equipment and/or devices of the present disclosure selectively use a communication service list to minimize time to align and lock on the communication signal.

The circuitry, system(s), method(s), equipment and/or devices of the present disclosure coordinate with components, modules, devices, or equipment to tune and lock on the communication signal wavelength and change the signal wavelength.

The circuitry, system(s), method(s), equipment and/or devices of the present disclosure use qualified events to minimize time on re-alignment, tuning, and lock on the communication signal. Qualified events include power loss, device or module removal, communication service changes, and signal integrity.

The circuitry, system(s), method(s), equipment and/or devices of the present disclosure will eliminate any local or remote provisioning or processes to provision the communication signal bit rate or wavelength.

The circuitry, system(s), method(s) equipment and/or devices of the present disclosure will not require any additional circuitry or equipment communication to coordinate alignment or CDR settings.

The circuitry, system(s), method(s), equipment and/or devices of the present disclosure will not require additional circuitry for local car remote provisioning and coordination, which results in lower costs.

The circuitry, system(s), method(s), equipment and/or devices of the present disclosure will minimize user installation errors or remote provisioning errors.

The circuitry, system(s), method(s), equipment and/or devices of the present disclosure will generate revenue quickly by eliminating installation complexities and errors.

### BRIEF DESCRIPTION OF THE DRAWINGS

FIG. 1 is a diagram illustrating prior art circuitry with static communication service bit rate

FIG. 2 is a diagram illustrating prior art circuitry with manual provisioning.

FIG. 3 is a diagram illustrating prior art circuitry with coordinated provisioning.

FIG. 4 is a diagram illustrating prior art circuitry with zero-touch or minimal provisioning.

FIG. 5A is a diagram illustrating a first version 200a of a first embodiment of the present disclosure comprising of two CDR circuitries and a microprocessor (MPU).

FIG. 5B is a diagram illustrating a second version 200b of a first embodiment of the present disclosure comprising of two CDR circuitries and a microprocessor (MPU).

FIG. 5C is a diagram illustrating a third version 200c of a first embodiment of the present disclosure comprising of two CDR circuitries and a microprocessor (MPU).

FIG. 5D is a diagram illustrating a fourth version 200d of a first embodiment of the present disclosure comprising of two CDR circuitries and a microprocessor (MPU).

FIG. 6A is a diagram illustrating a first version 200e of a second embodiment or the present disclosure comprising two CDR circuitries, two RCV circuitries, and a microprocessor (MPU).

FIG. 6B is a diagram illustrating a second version 200f of a second embodiment of the present disclosure comprising two CDR circuitries, two RCV circuitries, and a microprocessor (MPU).

FIG. 6C is a diagram illustrating a third version 200g of a second embodiment of the present disclosure comprising two CDR circuitries two RCV circuitries, and a microprocessor (MPU).

FIG. 6D is a diagram illustrating a fourth version 200h of a second embodiment of the present disclosure comprising two CDR circuitries, two RCV circuitries, and a microprocessor (MPU).

FIG. 7A is a diagram illustrating a first version 200i of a third embodiment of the present disclosure comprising two CDR circuitries, a RCV circuitry, a XMT circuitry, and a microprocessor (MPU).

FIG. 7B is a diagram illustrating a second first version 200j of a third embodiment of the present disclosure comprising two CDR circuitries, a RCV circuitry, a XMT circuitry, and a microprocessor (MPU).

FIG. 7C is a diagram illustrating a third version 200k of a third embodiment of the present disclosure comprising two CDR circuitries a RCV circuitry, a XMT circuitry, and a microprocessor (MPU).

FIG. 7D is a diagram illustrating a fourth version 200l of a third embodiment of the present disclosure comprising two CDR circuitries, a RCV circuitry, a XMT circuitry, and a microprocessor (MPU).

FIG. 8A is a diagram illustrating a first version 200m of a fourth embodiment of the present disclosure comprising two CDR circuitries, two RCV circuitries, two XMT circuitries, and a microprocessor (MPU).

FIG. 8B is a diagram illustrating a second version 200n of a fourth embodiment of the present disclosure comprising two CDR circuitry, two RCV circuitries, two XMT circuitries, and a microprocessor (MPU).

FIG. 8C is a diagram illustrating a third version 200o of a fourth embodiment of the present disclosure comprising two CDR circuitries, two RCV circuitries two XMT circuitries, and a microprocessor (MPU).

FIG. 8D is a diagram illustrating a fourth version 200p of a fourth embodiment of the present disclosure comprising two CDR circuitries, two RCV circuitries, two XMT circuitries, and a microprocessor (MPU).

FIG. 9 is a diagram illustrating four versions 200q1-200q4 of a fifth embodiment of the present disclosure comprising of two CDR circuitries, a microprocessor (MPU), and two ports (PORT).

FIG. 10 is a diagram illustrating four versions 200r1-200r4 of a sixth embodiment of the present disclosure comprising of two CDR circuitries, two RCV circuitries, a microprocessor (MPU), and two ports (PORT).

FIG. 11 is a diagram illustrating tour versions 200s1-200s4 of a seventh embodiment of the present disclosure comprising of two CDR circuitries, a RCV circuitry, a XMT circuitry, a microprocessor (MPU), and two ports (PORT).

FIG. 12 is a diagram illustrating four versions 200t1-200t4 of an eighth embodiment of the present disclosure comprising of two CDR circuitries, two RCV circuitries, two XMT circuitries, a microprocessor (MPU), and two ports (PORT).

FIG. 13 is a diagram illustrating a flow chart describing the communication service list.

FIG. 14 is a diagram illustrating a prioritized list of communication services list.

FIG. 15 is a diagram illustrating a flow chart on the auto-align operation of the present disclosure.

FIGS. 16A-16B are diagrams illustrating a flow chart on the auto-align and tuning operation of the present disclosure involving a port (PORT).

FIGS. 17A-17B are diagrams illustrating information received from a component, module, device, or equipment via a management interface to create a communication services list.

FIGS. 18A-18B are diagrams illustrating other information received from a component, module, device, or equipment via a management interface.

FIGS. 19A-19C are diagrams illustrating an example of a DWDM communication service list.

FIG. 20 is a table illustrating SFP Device variants, speeds, technology, and SFP port compatibility.

FIG. 21 is a table listing sources of information used by the microprocessor to determine appropriate wav multiplexing transmit and/or receive wavelength settings.

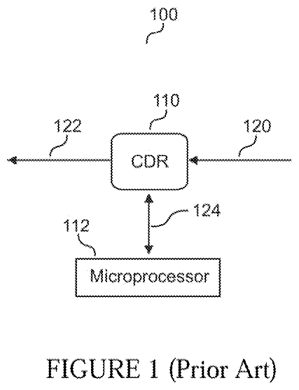

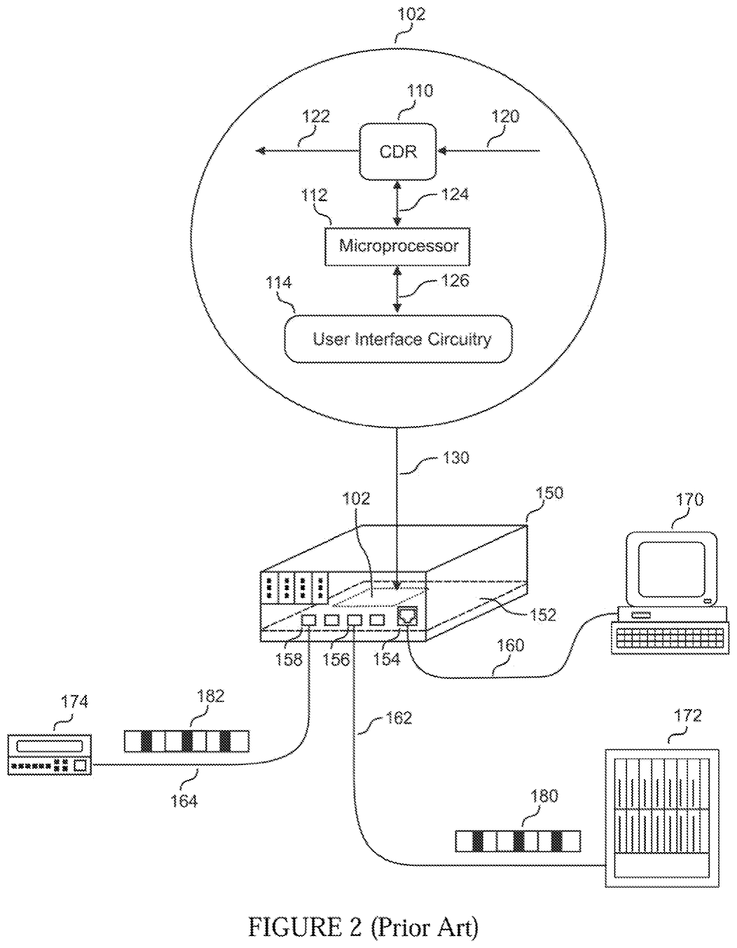

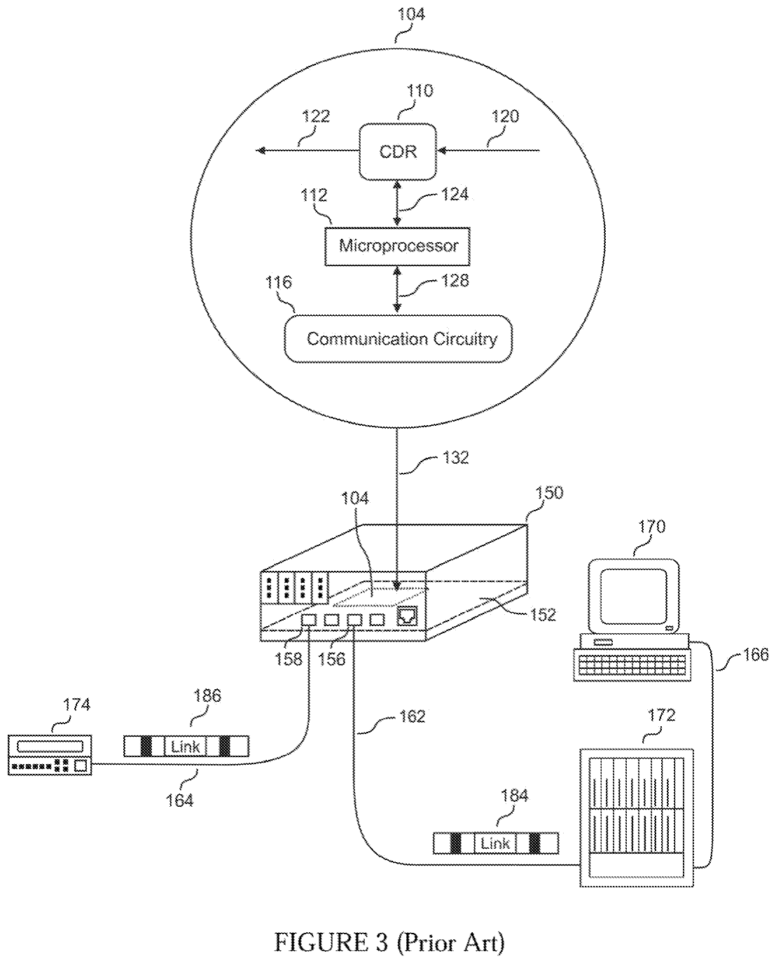

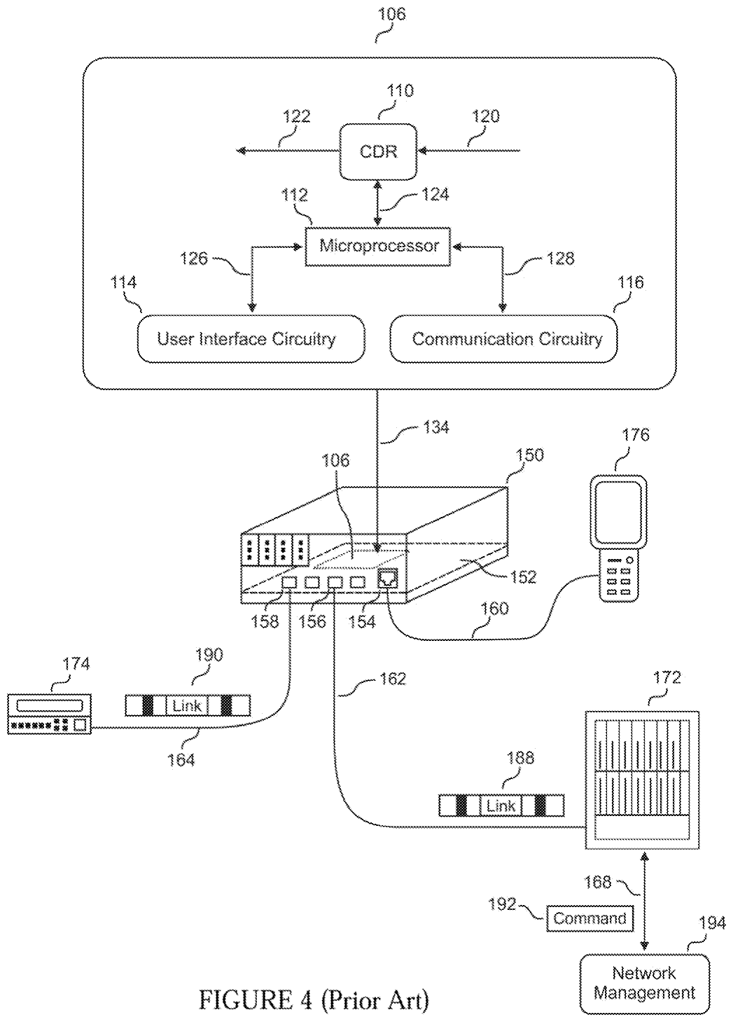

### DETAILED DESCRIPTION

The circuitry, system(s), method(s), equipment and/or device(s) of the present disclosure automatically align the communication signal using at least one clock and data rate recovery (CDR) circuitry and a microprocessor (MPU). Communication services can be represented by various communication signals with unique structures and bit rates. A partial list of these unique high speed communication signals are 10GELAN, 10GEWAN, CPRI7, eCPRI, OC-192 SONET, 10GFC, 16GFC, 28GFC, 32GFC, 64GFC, 128GFC, OTNIe, OTN2, OTN2e, USB3.1., G-PON, GE-PON, 10G-EPON, XG-PON, XGS-PON, NG-PON2, 25GS-PON, 50G-EPON, 50G-GPON, 100G/200GPON, Super-PON, and others.

In a second embodiment, the circuitry, system(s), method(s), equipment and/or device(s) of the present disclosure, two CDR and a MPU are connected to two receive (RCV) circuitry.

In a third embodiment, the circuitry, system(s), method(s), equipment and/or device(s) of the present disclosure, two CDRs and a MPU are connected to RCV and transmit circuitry (XMT).

In a fourth embodiment, the circuitry, system(s), method(s), equipment and/or device of the present disclosure, two CDRs and a MPU are connected to two RCVs and two XMTs.

In a fifth embodiment, the circuitry, system(s), method(s), equipment and/or device(s) of the present disclosure, two CDRs, and MPU circuitry, and two PORTs are interconnected.

In a sixth embodiment, the circuitry, system(s), method(s), equipment and/or device(s) of the present disclosure, two CDRs, a microprocessor (MPU), two RCV, and two PORTs are interconnected.

In a seventh embodiment, the circuitry, system(s), method(s), equipment and/or device(s) of the present disclosure, two CDRs, a MPU, a RCV, a XML and two PORTs are interconnected.

In an eighth embodiment, the circuitry, system(s), method(s), equipment and/or device(s) of the present disclosure, two CDRs, a MPU, a two RCV, a two XMTs, and two PORTs are interconnected.

There are different CDR circuitry design architectures, methodologies and approaches. The CDR circuitry architecture, design, and implementation are determined by the communication signal, the circuitry application, cost, supply chain, and/or manufacturing. The present disclosure utilizes any CDR circuitry or architecture appropriate to the communication service and application, equipment performance and design, and costs. For example, 10G and higher GPON communication service technologies require fast CDR synchronization for upstream burst-mode. A communication service with multilevel PAM-4 signal requires a non NRZ CDR circuitry such as a baud-rate CDR with a Mueller-Mueller phase detector. A 100 Gb/s quad-lane communication service may require a phase-interpolator (PI)-based clock and data recovery (CDR) using multi-phase delay-locked loop (MDLL).

The appropriate CDR circuitry detects the communication signal hit, phase, or symbol transitions to extract or calculate a clock or timing from the signal stream or a waveform. The extracted or recovered clock is used to align or tune to the incoming or received communication signal, reference Clock, or an external clock. The CDR will then re-clock the incoming or received communication signal to reduce timing impairments such as jitter, wander, and frequency mismatches. The CDR circuitry will regenerate the communication signal during the re-clocking process. The re-clocked and regenerated communication signal provides a very accurate and quality signal for other circuitry, devices, and/or networks to reliably interface. The clock data recovery circuitry (CDR) in this embodiment can be comprised of integrated circuits (hardware), software, or a combination of analog, digital, or analog and digital hardware and software. More specifically, the CDR can be implemented with discrete integrated circuits, field programmable gate arrays (FPGA), application specific integrated circuit (ASIC), system-on-a-chip (SoC), microprocessors, microcontrollers, digital signal processors (DSP), analog signal processors (ASP), or other similar hardware circuitry, software programming, or a combination of hardware and software.

The microprocessor (MPS) can be any microprocessor or microprocessor variant such as as microcontroller (MCU), a digital signal processor (DSP), a graphics processing unit (GPU), a system on chip (SoC), a finite state machine (FSM), configurable logic devices PLD, FPGA, etc.), application specific integrated circuit (ASIC), or any other circuitry accessing memory devices (EEPROM, NVRAM, etc), that provides changes from one state to another in response to a change of state. In the circuitry, system(s), method(s), equipment and/or device(s) of the present disclosure, the MPU will store a sequence of settings to initialize and configure the CDR. There are integrated CDRs which initialize and configure to a specific default operation. The microprocessor (MPU) with discreet and integrated CDRs will also provide settings to align the CDR to a list of communication signal bit rates. This list represents the communication signal hit rates the CDR will interface. This list is based upon the implementation and application of the CDR. The list will represent the appropriate data for the CDR to align. Due to the variations of design architectures, methodologies, and approaches, each CDR will have a specific or proprietary data type and format and process to align.

In the circuitry, system(s), method(s), equipment and/or device(s) of the present disclosure, Connection (CXN) is defined as any medium to interface other circuitry, devices, or equipment. A Connection (CXN) can be de-fined as printed circuit board (PCB) traces on a PCB assembly or metal interconnects within an integrated circuit to interface other circuitry to process the communication signal. These other circuitries can be an electrical-to-optical conversion integrated circuit, microprocessor, crosspoint switch, retimer, digital signal processors (DSP), field programmable gate-array (FPGA), application specific integrated circuits (ASIC), or other signal interface circuitry. Connection (CXN) can also be defined as a mechanical component to interconnect and interface a PCB circuitry assembly to process the communication signal.

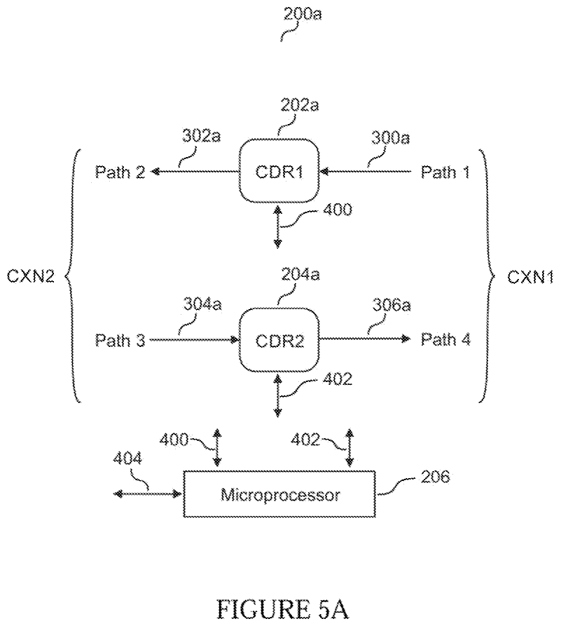

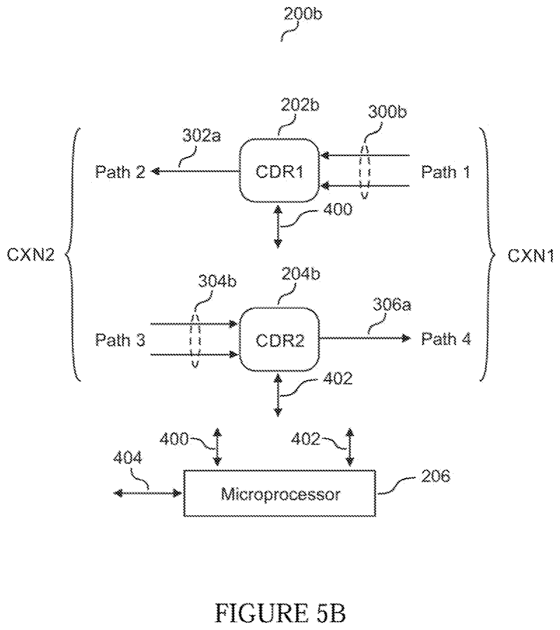

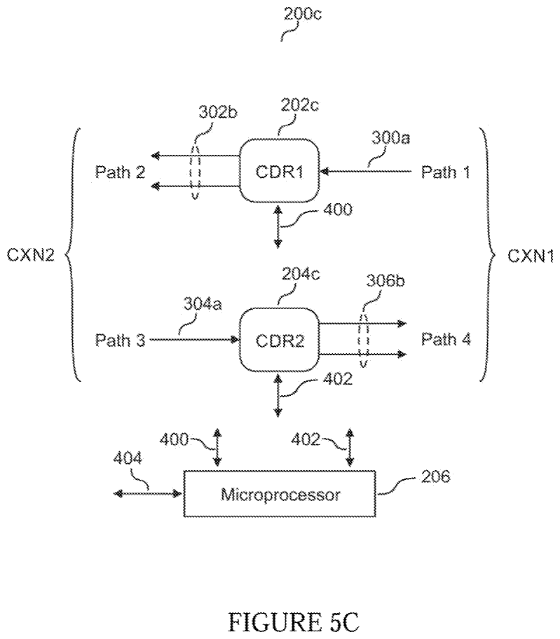

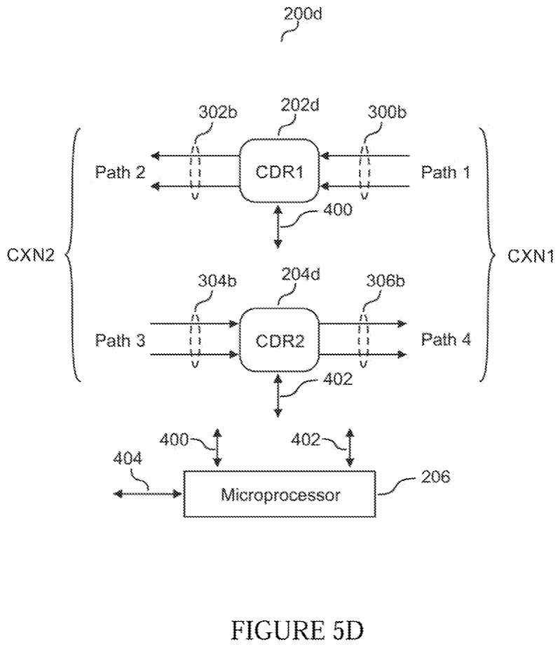

In the circuitry, system(s), method(s), equipment and/or device(s) of the present disclosure, the embodiments 200a-200t4 as illustrated in FIGS. 5A-12 describe various different analog and digital signal interconnection types between and among CDRs, RCVs, XMTs, MPUs, and/or PORTs. These signal interconnection types are represented as exclusively single-ended, a combination of single-ended and differential or exclusively differential. Single-ended connections are input and/or output connections using a signal referenced to a ground. This single-ended signal is an analog or digital signal. The use of single-ended signals, differential signals, or a combination of both are connected through discrete integrated chips or highly integrated chips. As such, the embodiments 200a-200t4 are individually implemented through or as a part of various design architectures such as system-on-a-chip (SoC), chip2module (C2M), chip2chip (C2C), chip2fabric (C2F), chip2embedded optics (C2EO) or co-packaged optics (CPO). These design architectures are known in the industry and represent different techniques to implement functionality through combining and connecting discrete integrated circuits, incorporating functionality into an integrated circuit, or a combination of both architectures implemented with discreet integrated circuit components of a printed circuit board (PCB), designed into a programmable integrated circuit or a combination of discreet and programmable integrated circuits. A programmable integrated circuit can be a field programmable gate array (FPGA), digital signal processor (DSP), system-on-chip (SoC) or a highly integrated processor which can implement all or a partial of the circuitry of the versions.

### FIGS. 5A-5D

In the circuitry, system(s), method(s), equipment an for device of the present disclosure, the embodiments as illustrated in FIGS. 5A-5D represent a group of related block diagrams versions 200a-200d of the circuitry of the present disclosure involving two connections; CXN1 and CXN2 and two signal paths each, CXN1 has two signal paths, Path 1 and Path 4. CXN2 has two signal paths. Path 2 and Path 3. Each version is comprised of two clock and data recovery (CDR) circuitries and microprocessor (MPU) circuitry. The two CDR circuitries and the MPU circuitry can be implemented with discreet integrated circuit components on a printed circuit board (PCB), designed into a preprogrammable integrated circuit or a combination of discreet and programmable integrated circuits. A programmable integrated circuit can be a field programmable gate array (FPGA), digital signal processor (DSP), system-on-chip (SoC), or within a highly integrated processor which can implement all or a partial of the circuitry of the versions.

### FIGS. 5A-5D (First Embodiment)

In the circuitry, system(s), method(s), equipment and/or device(s) of the present disclosure, the embodiments as illustrated in FIGS. 5A-5D versions 200a-200d each comprise a microprocessor (MPU) 206. The microprocessor (MPU) 206 interfaces CDR1 202a-202d through connection or interface 400 and CDR2 204a-204d through connection or interface 402.

FIG. 5A illustrates the version 200a of the first embodiment of the present disclosure comprising clock data recovery circuitry CDR1 202a and CDR2 204a, and a microprocessor circuitry MPU 206. CXN1 comprises a Path 1 representing an input single-ended signal 300a and a Path 4 representing an output single-ended signal 306a. CXN2 comprises a Path 2 representing an output single-ended signal 302a and a Path 3 representing an input single-ended signal 304a.

Path 1 (Version 200a) input single-ended signal 300 connects to the input of CDR1 202a.

Path 2 (Version 200a) output single-ended signal 302a connects to the output of CDR1 702a.

Path 3 (Version 200a) input single-ended signal 304a connects to the input of CDR2 204a.

Path 4 (Version 200a) output single-ended signal 306a connects to the output of CDR2 204a.

FIG. 5B illustrates the version 200b of the first embodiment of the present disclosure comprising clock data recovery circuitry CDR1 202b and CDR2 204b circuitry, and a microprocessor circuitry (MPU) 206. CXN1 comprises a Path 1 representing an input differential signal 300b and a Path 4 representing an output single-ended signal 306a. CXN2 comprises a Path 2 representing an output single-ended signal 302a and a Path 3 representing an input differential signal 304b.

Path 1 (Version 200b) input differential signal 300b connects to the input of CDR1 202b.

Path 2 (Version 200b) output single-ended signal 302a connects to the output of CDR1 202b.

Path 3 (Version 200b) input differential signal 304b connects to the input of CDR2 204b.

Path 4 (Version 200b) output single-ended signal 306a connects to the output of CDR2 204b.

FIG. 5C illustrates the version 200c of the first embodiment of the present disclosure comprising clock data recovery circuitry CDR1 202c and CDR2 204c, and a microprocessor circuitry MPU 206. CXN1 comprises a Path 1 representing an input single-ended signal 300a and a Path 4 representing an output differential signal 306b. CXN2 comprises a Path 2 representing an output differential signal 302b and a Path 3 representing an input single-ended signal 304a.

Path 1 (Version 200c) input single-ended signal 300a connects to the input of CDR1 202c.

Path 2 (Version 200c) output differential signal 302b connects to the output of CDR1 202c.

Path 3 (Version 200c) input single-end signal 304a connects to the input of CDR2 204c.

Path 4 (Version 200c) output differential signal 306b connects to the output of CDR2 204c.

FIG. 5D illustrates the version 200d of the first embodiment of the present disclosure comprising clock data recovery circuitry CDR1 202d and CDR2 204d, and a microprocessor circuitry MPU 206 circuitry. CXN1 comprises a Path 1 representing an input differential signal 300b and a Path 4 representing an output differential signal 306b. CXN2 comprises a Path 2 representing an output differential signal 302b and a Path 3 representing an input differential signal 304b.

Path 1 (Version 200d) input differential signal 300b connects to the input of CDR1 202d.

Path 2 (Version 200d) output differential signal 302b connects to the output of CDR1 202d.

Path 3 (Version 200d) input differential signal 304b connects to the input of CDR2 204d.

Path 4 (Version 200d) output differential signal 306b connects to the output of CDR2 204d.

A microprocessor circuitry (MPU) 206 connects to CDR1 202a-202d and CDR2 204a-204d through connections 400 and 402, respectively. The MPU 206 communicates a series of commands to CDR1 202a-202d and CDR2 204a-204d for initialization and provisioning for signal bit rate settings, signal output patterns and control, and to determine CDR and signal performance and status. The MPL1 206 will determine performance and status by reading, the CDR1 202a-202d and CDR2 204a-204d software registers or by sensing a voltage level from the CDR1 202a-202d and CDR2 204a-204d circuitry pin connectors. MPU 206 may also provision CDR1 202a-202d and CDR2 204a-204d to output a signal with a specific pattern or disable the output to minimize signal noise or corrupted data to affect other circuitry, systems, and the network during the version 200a-200d initialization or operation. When a communication signal. 300a-300b is present on Path 1 of connection CXN1, CDR1 202a-202d will attempt to align and lock to the communication signal 300a-300b bit rate. If CDR1 202a-202d does not lock to the communication signal 300a-300b bit rate, CDR1 202a-202d will indicated a non-locked status to the microprocessor (MPU) 206 through interface 400. The MPU 206 will communicate to CDR1 202a-202d non-locked status to supervisory circuitry through interface 404. The microprocessor (MPU) 206 will then provision the CDR1 202a-202d with the next sequential bit rate setting from the signal bit rate list. The CDR1 202a-202d will then attempt to align and lock with the new signal bit rate. If the CDR1 202a-202d 202a-202d still does not align and lock to the new signal bit rate, the MPU 206 will repeat or cycle the process and interactions with CDR1 202a-202d using the next sequential bit rate setting on the list. If the CDR1 202a-202d locks to the communication signal 300a-300b bit rate, CDR1 202a-202d will indicate a locked status to MPU 206 through interface 400. The CDR1 202a-202d will re-clock and regenerate the communication signal 302a-302b on Path 2 of connection CXN2. The MPU 206 will process and store the CDR1 202a-202d locked status and the communication signal bit rate setting. The MPU 206 will communicate the CDR1 202a-202d locked status to supervisory circuitry through interface 404. The MPU 206 will then automatically provision CDR2 204a-204d with the CDR1 202a-202d locked communication signal bit rate settings and any applicable activation and/or initialization settings, CDR2 204a-204d will align to the communication signal 304a-304b from Path 3 connection 2 (CXN2). CDR 204a-204d will then re-clock, re-generate, and transmit the communication signal 306a-306b to Path 4 connection 1 (CXN1).

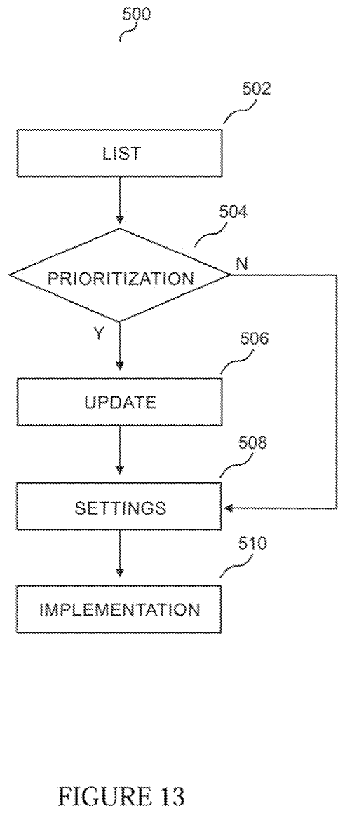

The processes and interactions describing the communication signal bit rate auto-alignment of among CDR1 202a-202d, CDR2 204a-204d, and MPV 206 are further discussed and illustrated in FIGS. 13-19C.

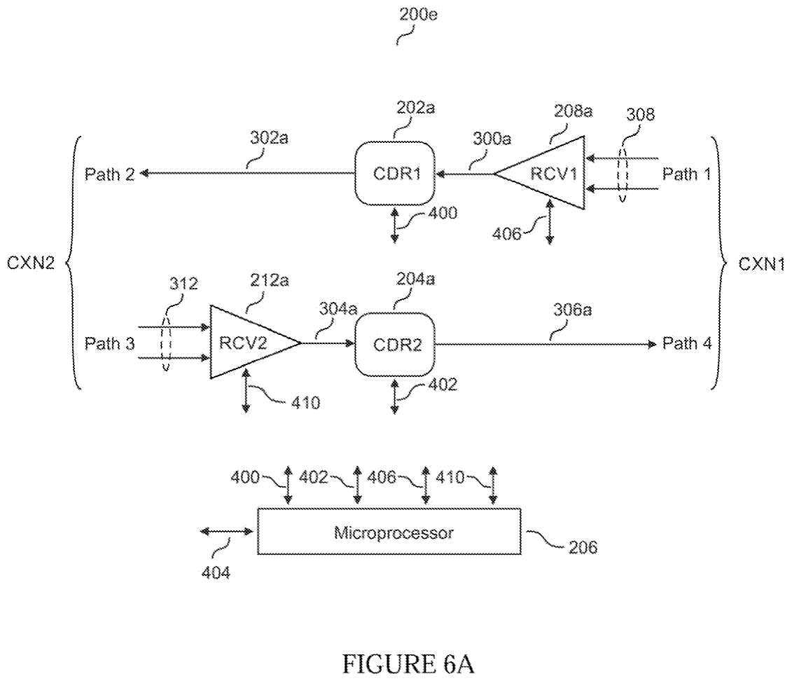

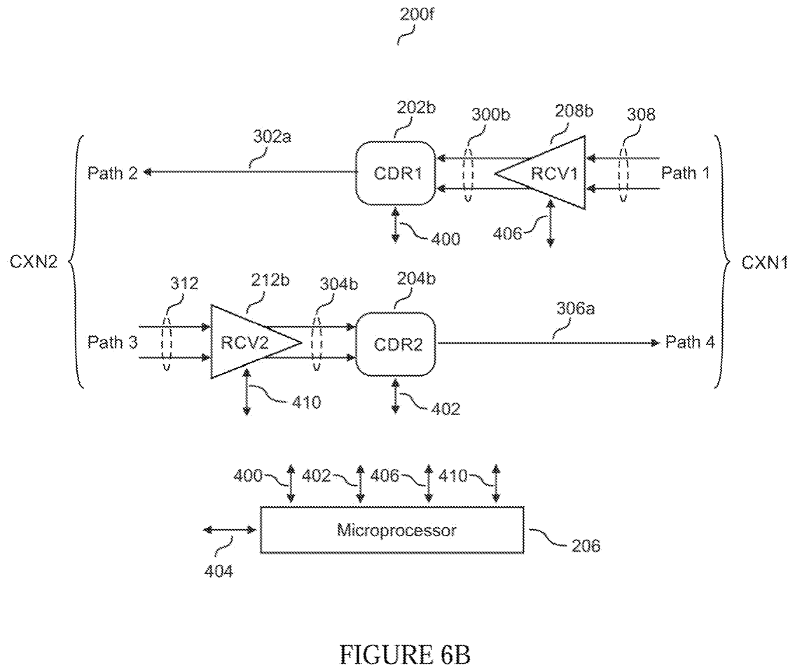

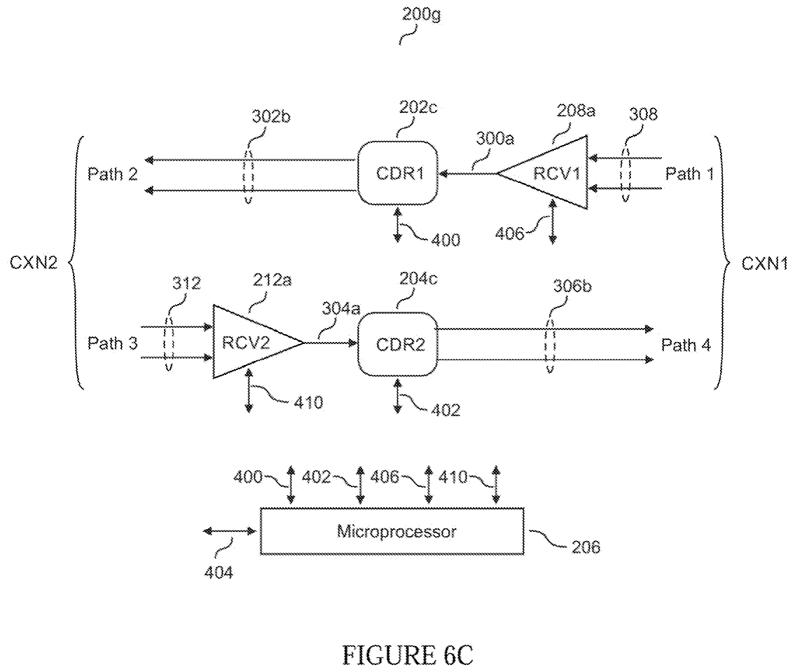

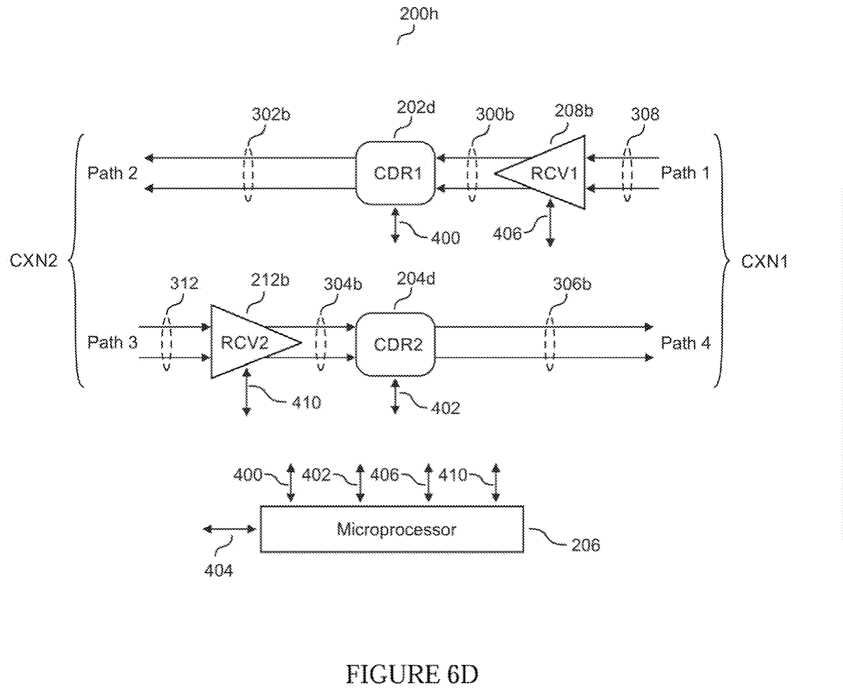

### FIG. 6A-6B (Second Embodiment)

In the circuitry, system(s), method(s), equipment and/or device(s) of the present disclosure, the second embodiment as illustrated in FIGS. 6A-6D represent a group of related block diagrams versions 200e-200h of the circuitry of the present disclosure involving two connections; CXN1 and CXN2 and two signal paths each. CXN1 has two signal paths, Path 1 and Path 4. CXN2 has two signal paths, Path 2 and Path 3. Each version is comprised of two clock and data recovery circuitries (CDR), a microprocessor circuitry (MPU), and two receive circuitries (RCV). The receive circuitry (RCV) interfaces communication signals from a wire(s), coaxial cable, fiber optic cable, or wireless transmission medium, The receive circuitry (RCV) is typically a signal buffer, or amplifier (i.e. broadband, limiting, pre-amplifier). The receive circuitry (RCV) may also include equalization to condition the communication signal. The communication signal from the connection (CXN) can be impaired from traversing through long length printed circuit boards (PCB) traces, signal interface connectors, SFP variant devices (described below), other communication devices, wired cables, optical fiber cables, or a combination of some or all. Impaired communication signals will require equalization or signal integrity to ensure the clock and data recovery circuitry (CDR) will accurately and reliability recover and extract the clock. The equalization circuitry removes inter-symbol interference (ISI), crosstalk, phase errors, and other signal impairments in the communication signal. Continuous-time linear equalizer (CTLE), feed-forward equalizer (FFE), and decision feedback equalizer (DFE) are the typical equalization schemes. The receive circuitry (RCV) may also include a phase or frequency detector circuitry. A phase or frequency detector circuitry can assist with clock recovery, The receive circuitry (RCV) may also provide dc-serialization and/or analog-to-digital circuitry (ADC) to reformat a single-ended analog or differential signal to a digital serial or parallel signal.

FIG. 6A illustrates the version 200e of the second embodiment of the present disclosure comprising clock data recovery circuitry CDR1 202a and CDR2 204a, receive circuitry RCV 208a and RCV2 212a, and a microprocessor circuitry MPU 206. CXN1 comprises a Path 1 representing an input differential signal 308 and a Path 4 representing an output single-ended signal 306a. CXN2 comprises a Path 2 representing an output single-ended signal 302a and a Path 3 representing an input differential signal 312.

Path 1 (Version 200e) input differential signal 308 connects to the input of RCV1 208a. Receive circuitry RCV1 208a outputs a signal-ended signal 300a to input of CDR1 202a.

Path 2 (Version 200e) output single-ended signal 302E connects to the output of CDR1 202a.

Path 3 (Version 200e) input differential signal 312 connects to the input of RCV2 212a. Receive circuitry RCV2 212a outputs a signal-ended signal 304a to the input of CDR2 204a.

Path 4 (Version 200e) output single-ended signal 306a connects to the output of CDR2 204a.

FIG. 6B illustrates the version 200f of the second embodiment of the present disclosure comprising dock data recovery circuitry CDR1 202b and CDR2 204b, receive circuitry RCV1 208b and RCV2 212b, and a microprocessor circuitry MPU 206. CAN1 comprises a Path 1 representing an input differential signal 308 and a Path 4 representing an output single-ended signal 306a. CXN2 comprises a Path 2 representing an output single-ended signal 302a and a Path 3 representing an input differential signal 312.

Path 1 (Version 200f) input differential signal 308 connects to the input of RCV1 208b. Receive circuitry RCV1 208b outputs a differential signal 300b to the input of CDR1 202b.

Path 2 (Version 200f) output single-ended signal 302a connects to the output of CDR1 202b.

Path 3 (Version 200f) input differential signal 312 connects to the input of RCV2 212b. Receive circuitry RCV2 212b outputs a differential signal 304b to the input of CDR2 204b.

Path 4 (Version 200f) output single-ended signal 306a connects to the output of CDR2 204b.

FIG. 6C illustrates the version 200g of the second embodiment of the present disclosure comprising clock data recovery circuitry CDR1 202c and CDR2 204c, receive circuitry RCV1 208a and RCV2 212a, and a microprocessor circuitry MPU 206. CXN1 comprises a Path 1 representing an input differential signal 308 and a Path 4 representing an output differential signal 306b. CXN2 comprises a Path 2 representing an output differential signal 302b and a Path 3 representing an input differential signal 312.

Path 1 (Version 200g) input differential signal 308 connects to the input of RCV1 208a. Receive circuitry RCV1 208a outputs a single-ended signal 300a to the input of CDR1 202c.

Path 2. (Version 200g) output differential signal 302b connects to the output of CDR1 202c.

Path 3 (Version 200g) input differential signal 312 connects to the input of RCV2 212a. Receive circuitry RCV2 212a outputs a single-ended signal 304a to the input of CDR2 204c.

Path 4 (Version 200g) output differential signal 306b connects to the output of CDR2 204c.

FIG. 6D illustrates the version 200h of the second embodiment of the present disclosure comprising, clock data recovery circuitry CDR1 202d and CDR2 204d, receive circuitry RCV1 208b and RCV2 212b, and a microprocessor circuitry MPU 206. CXN1 comprises a Path 1 representing an input differential signal 308 and a Path 4 representing an output differential signal 306b. CXN2 comprises a Path 2 representing an output differential signal 302b and a Path 3 representing an input differential signal 312.

Path 1 (Version 200h) input differential signal 308 connects to the input of RCV1 208b. Receive circuitry RCV1 208b outputs a differential signal 300b to the input of CDR1 202d.

Path 2 (Version 200h) output differential signal 302b connects to the output of CDR1 202d.

Path 3 (Version 200h) input differential signal 312 connects to the input of RCV2 212b. Receive circuitry RCV2 212b outputs a differential signal 304b to the input of CDR2 204d.

Path 4 (Version 200h) output differential signal 306b connects to the output of CDR2 204d.

A microprocessor circuitry (MPU) 206 connects to CDR1 202a-202d, CDR2 204a-204d, RCV1 208a-208b, and RCV2 212a-212b through connections 400, 402, 406, and 410 respectively. MPU 206 communicates a series of commands to CDR1 202a-202d and CDR2 204a-204d for initialization and provisioning communication bit rate settings, signal output patterns and control, and to determine CDRs performance and status. The MPU 206 will determine performance and status by reading the CDR1 202a-202d and CDR2 204a-204d software registers or by sensing a voltage level from the CDR1 202a-209d and CDR2 204a-204d circuitry pin connectors. MPU 206 may also provision CDR1 202a-202d and CDR2 204a-204d to output a signal with a specific pattern or disable the output to minimize signal noise or corrupted data to affect other circuitry, systems, and the network during the version initialization or operation. Depending upon the application, MPU 206 can communicate initialization and provisioning settings to RCV1 208a-208b and RCV2 212a-212b. The MPU 206 may provision RCV1 208a-208b and/or RCV2 212a-212b with different amplification and equalization settings. If RCV 208a-208b and RCV2 212a-212b is a buffer or an amplifier with a fixed gain setting, connection 406 and 410 to MPU 206 may not be required. Furthermore, the MPU 206 may request and received performance and operational status of RCV1 208a-208b and RCV2 212a-212b. When a communication signal 308 is present on Path 1 of connection CAN1, RCV1 208a-208b will buffer or amplify the communication signal 300a-300b. RCV1 208a-208b may also equalize the communication signal 308 to remove any signal impairments and/or convert the differential communication signal to a non-differential communication signal to interface CDR1 202a-202d. CDR1 202a-202d will attempt to align and lock to the communication signal bit rate. If CDR1 202a-202d does not align and lock to the communication signal 300a-300b bit rate, CDR1 202a-202d will indicated a non-locked status to the microprocessor (MPU) 206 through connection 400. The MPU 206 will communicate the CDR1 202a-202d non-locked status to supervisory circuitry through connection 404. The microprocessor (MPU) 206 will then provision the CDR1 202a-202d with the next sequential bit rate setting from the communication signal bit rate list. The CDR1 202a-202d will attempt again to align and lock to the communication signal bit rate from connection 300a-300b. If the CDR1 202a-202d still does not align and lock to the communication signal bit rate, the process and interactions between the CDR1 202a-202d and the MPU 206 will repeat using the next sequential bit rate setting. If the CDR1 202a-202d aligns and locks to the communication signal bit rate, CDR1 202a-202d will indicate a locked status to MPU 206 through connection 400. The CDR1 202a-202d will re-clock and regenerate the communication signal 307a-302b on Path 2 of connection CXN2. The MPU 206 will process and store the CDR1 202a-202d locked status and the communication signal bit rate setting. The MPU 206 will communicate the CDR1 202a-202d locked status to supervisory circuitry through connection 404. The MPU 206 will then automatically provision CDR2 204a-204d with the CDR1 202a-202d locked communication signal bit rate settings and any applicable activation and/or initialization settings. CDR2 204a-204d will align to the communication signal 304a-304b from Path 3 connection 2 (CXN2). CDR2 204a-204d will then re-clock, re-generate, and transmit the communication signal 306a-306b to Path 4 connection 1 (CXN1).

The processes and interactions describing the communication signal bit rate auto-alignment of among CDR1 202a-202d, CDR2 204a-204d, and MPU 206 are further discussed and illustrated in FIGS. 13-19.

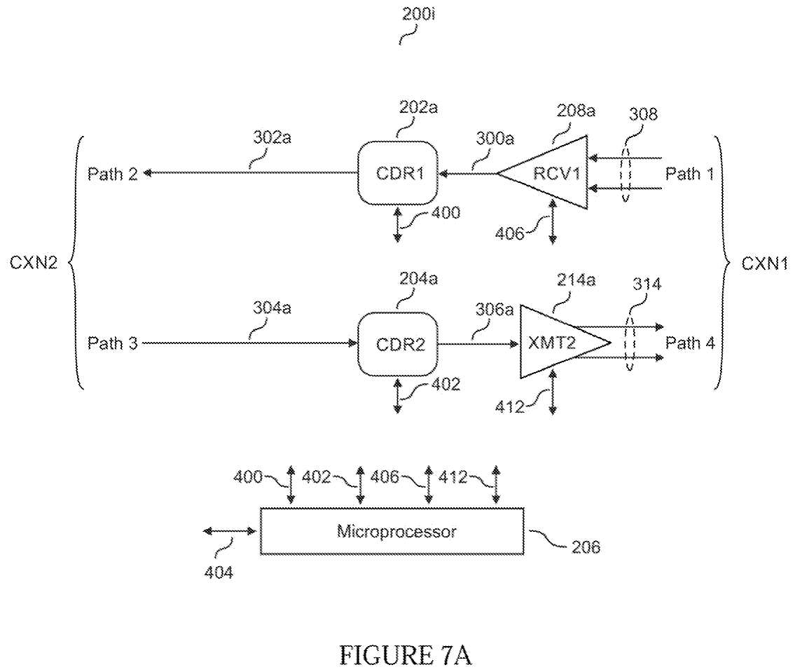

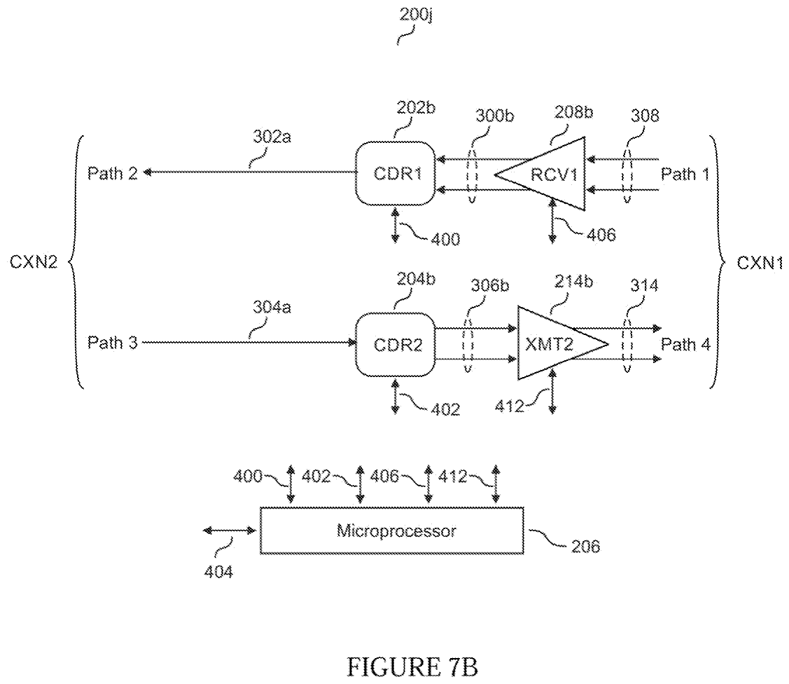

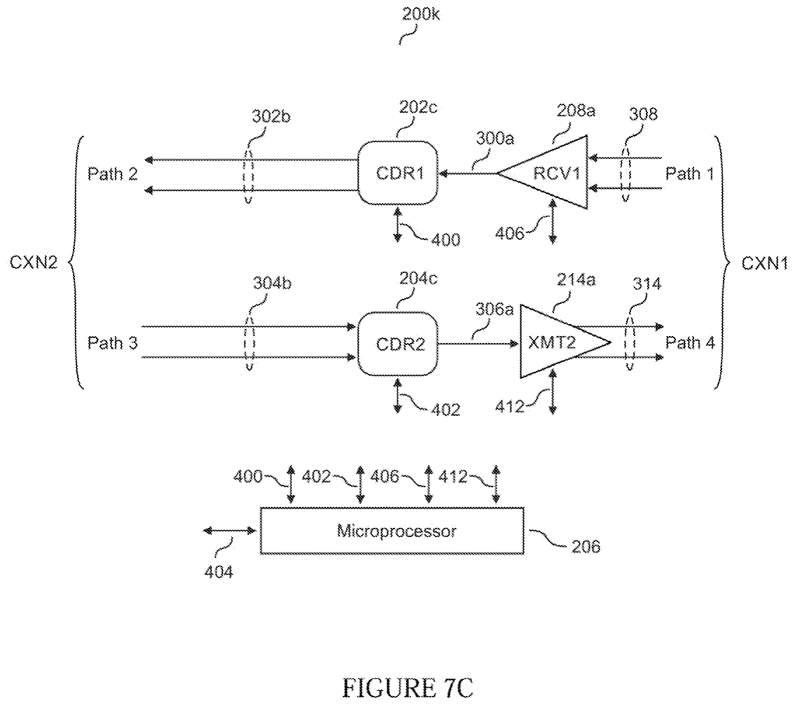

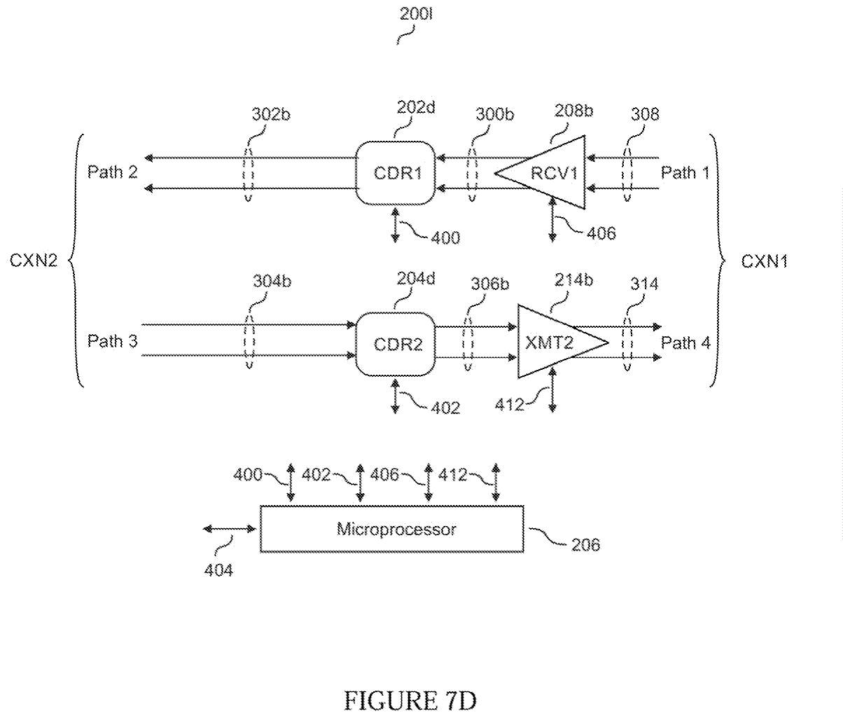

### FIG. 7A-7E (Third Embodiment)

In the circuitry, system(s), method(s), equipment and/or device(s) of the present disclosure, the third embodiment as illustrated in FIGS. 7A-7D represent a group of related block diagrams versions 200i-200l of the circuitry of the present disclosure involving two connections; CXN1 and CXN2 and two signal paths each. CXN1 has two signal paths, Path and Path 4. CXN2 has two signal paths, Path 2 and Path 3. Each version is comprised of two clock and data recovery circuitries (CDR), a microprocessor circuitry (MPU), a receive circuitry (RCV), and a transmit circuitry (XMT). A transmit circuitry (XMT) is typically a buffer or amplifier circuitry. The transmit circuitry (XMT) receives and process communication signals for transmission to a component, an antenna, a device, a module, or an equipment. The transmit circuitry (XMT) may also provide signal modulation and/or A/D or D/A signal conversion. The transmit circuitry (XMT) may also provide pre-emphasis or pre-equalization to the transmitted signal to interface different media such as cable, other devices, or printed circuit board traces to compensate for impairments from the path connections. A digital signal processor (DSP), system on a chip (SoC), an ASIC, FPGA, or a highly integrated processor with analog and digital processing can be used to integrate the XMT, CDR, and RCV circuitries. A retimer is a commercially available AMC integrating the XMT, RCV, and CDR circuitries.

FIG. 7A illustrates the version 200i of the third embodiment of the present disclosure comprising clock data recovery circuitry CDR1 202a and CDR2 204a, receive circuitry RCV1 208a and transmit circuitry XMT2 214a, and a microprocessor circuitry MPU 206. CXN1 comprises a Path 1 representing an input differential signal 308 and a Path 4 representing an output differential signal 314. CXN2 comprises a Path 2 representing an output single-ended signal 302a and a Path 3 representing an input single-ended signal 304a.

Path 1 (Version 200i) input differential signal 308 connects to the input of RCV1 208a. Receive circuitry RCV1 208a outputs a signal-ended signal 300a to the input CDR1 202a.

Path 2 (Version 200i) output single-ended signal 302a connects to the output of CDR1 202a.

Path 3 (Version 200i) input single-ended signal 304a connects to the input of CDR2 204a. Clock data recovery circuitry CDR2 204a outputs a single-ended signal 306a to the input of XMT2 214a.

Path 4 (Version 200i) output differential signal 314 connects to the output of XMT2 714a.

FIG. 7B illustrates the version 200j of the third embodiment of the present disclosure comprising clock data recovery circuitry CDR1 202b and CDR2 204b, receive circuitry RCV1 208b and transmit circuitry XMT2 214b, and a microprocessor circuitry MPU 206. CXN1 comprises a Path 1 representing an input differential signal 308 and a Path 4 representing an output differential signal 314. CXN2 comprises a Path 2 representing an output single-ended signal 302a and a Path 3 representing an input single-ended signal 304a.

Path 1 (Version 200j) input differential signal 308 connects to the input of RCV1 208b. Receive circuitry RCV 208b outputs a differential signal 300b to the input CDR1 202b.

Path 2 (Version 200j) output single-ended signal 302a connects to the output of CDR1 702b.

Path 3 (Version 200j) input single-ended signal 304a connects to the input of CDR2 204b. Clock data recovery circuitry CDR2 204b outputs a differential signal 306b to the input of XMT2 214b.

Path 4 (Version 200j) output differential signal 314 connects to the output of XMT2 214b.

FIG. 7C illustrates the version 200k of the third embodiment of the present disclosure comprising clock data recovery circuitry CDR1 202c and CDR2 204c, receive circuitry RCV1 208a and transmit circuitry XMT2 214a, and a microprocessor circuitry MPU 206. CXN1 comprises a Path 1 representing an input differential signal 308 and a Path 4 representing an output differential signal 314. CXN2 comprises a Path 2 representing an output differential signal 302b and a Path 3 representing: an input differential signal 304b

Path 1 (Version 200k) input differential signal 308 connects to the input of RCV1 208a. Receive circuitry RCV1 208a outputs a signal-ended signal 300a to the input CDR1 202c.

Path 2 (Version 200k) output differential signal 302b connects to the output of CDR1 202c.

Path 3 (Version 200k) input differential signal 304b connects to the input of CDR2 204c. Clock data recovery circuitry CDR2 204c outputs a single-ended signal 306a to the input of XMT2 214a.

Path 4 (Version 200k) output differential signal 314 connects to the output of XMT2 214a.

FIG. 7D illustrates the version 200l of the third embodiment of the present disclosure comprising, clock data recovery circuitry CDR1 202d and CDR2 204d, receive circuitry RCV1 208b and transmit circuitry XMT2 214b, and a microprocessor circuitry MPU 206. CXN1 comprises a Path 1 representing an input differential signal 308 and a Path 4 representing an output differential signal 314. CXN2 comprises a Path 2 representing an output differential signal 302b and a Path 3 representing an input differential signal 304a.

Path 1 (Version 200l) input differential signal 308 connects to the input of RCV1 208b. Receive circuitry RCV1 208b outputs a differential signal 300b to the input CDR1 202d.

Path 2 (Version 200l) output differential signal 302b connects to the output of CDR1 202d.

Path 3 (Version 200l) input differential signal 304b connects to the input of CDR2 204d. Clock data recovery circuitry CDR2 204d outputs a differential signal 306b to the input of XMT2 214b.

Path 4 (Version 200l) output differential signal 314 connects to the output of XMT2 214b.

A microprocessor circuitry (MPU) 206 connects to CDR1 202a-202d , CDR2 204a-204d , RCV1 208a-208b and XMT2 214a-214b through connections 400, 402, 406, and 412 respectively. MPU 206 communicates a series of commands to CDR1 202a-202d and CDR2 204a-204d for initialization and provisioning communication bit rate settings, signal output patterns and control, and to determine CDRs performance and status. The MPU 206 will determine performance and status by reading the CDR1 202a-202d and CDR2 204a-202d software registers or by sensing a voltage level from the CDR1 202a-202d and CDR2 204a-204d circuitry pin connectors. MPU 206 may also provision CDR1 202a-202d and CDR2 204a-204d to output a signal with a specific pattern or disable the output to minimize signal noise or corrupted data to affect other circuitry, systems, and the network during the version initialization or operation. Depending upon the application, MPU 206 can communicate initialization and provisioning settings to RCV1 208a-208b. The MPU 206 may provision RCV1 208a-208b with different amplification and equalization settings. If RCV1 208a-208b is a buffer or area amplifier with a fixed gain setting, connection 406 to MPU 206 may not be required. Furthermore, the MPU 206 may request and received performance and operational status of RCV1 208a-208b. Depending upon the application, MPL1 206 can communicate initialization and provisioning settings to XMT2 214a-214b. The MPU 206 may provision XMT2 214a-214b with amplification, modulation, reformatting, or pre-equalization setting to interface the differential signal 314 for interfacing Path 4 connections CXN1. When a communication signal 308 is present on Path 1 of connection CXN1, RCV1 208a-208b will buffer or amplify the communication signal. RCV1 208a-208b may also equalize the communication signal 308 to remove any signal impairments and/or convert the differential communication signal to a non-differential communication signal to interface CDR1 202a-202d. CDR1 202a-202d will attempt to align and lock to the communication signal bit rate. If CDR1 202a-202d does not align and lock to the communication signal 300a-300b bit rate. CDR1 202a-202d will indicated a non-locked status to the microprocessor (MPU) 206 through connection 400. The MPU 206 will communicate the CDR1 202a-202d non-locked status to supervisory circuitry through connection 404. The microprocessor (MPU) 206 will then provision the CDR1 202a-202d with the next sequential bit rate setting from the communication signal hit rate list. The CDR1 202a-202d will attempt again to align and lock to the communication signal bit rate from connection 300a-300b. If the CDR1 202a-202d does not align and lock to the communication signal bit rate, the process and interactions between the CDR1 202a-202d and the MPU 206 will repeat using the next sequential bit rate setting. If the CDR1 202a-202d aligns and locks to the communication signal bit rate. CDR1 202a-202d will indicate a locked status for MPU 206 through connection 400. The CDR1 202a-202d will re-clock and regenerate the communication signal 302a-302b on Path 2 of connection CXN2. The CDR1 202a-202d will also output a message to MPU 206 that CDR1 202a-202d is locked. The MP 206 will process and store the CDR1 202a-202d locked status and the communication signal bit rate setting. The MPU 206 will communicate the CDR1 202a-202d locked status to supervisory circuitry through connection 404. The MPU 206 will then automatically provision CDR2 204a-204d with the CDR1 202a-202d locked communication signal bit rate settings and any applicable activation or initialization settings. CDR2 204a-204d will then align and lock to the communication signal bit rate from connection 304a-304b. CDR2 204a-204d will re-clock and regenerate the locked communication signal 306a-306b to XMT2 214a-214b. XMT2 214a-214b may perform signal amplification, buffering, format conversion, or conditioning on Path 4 of connection CXN1.

The processes and interactions describing the communication signal bit rate auto-alignment of among CDR1 202a-202d, CDR2 204a-204d, and MPU 206 are further discussed and illustrated in FIGS. 13-19.

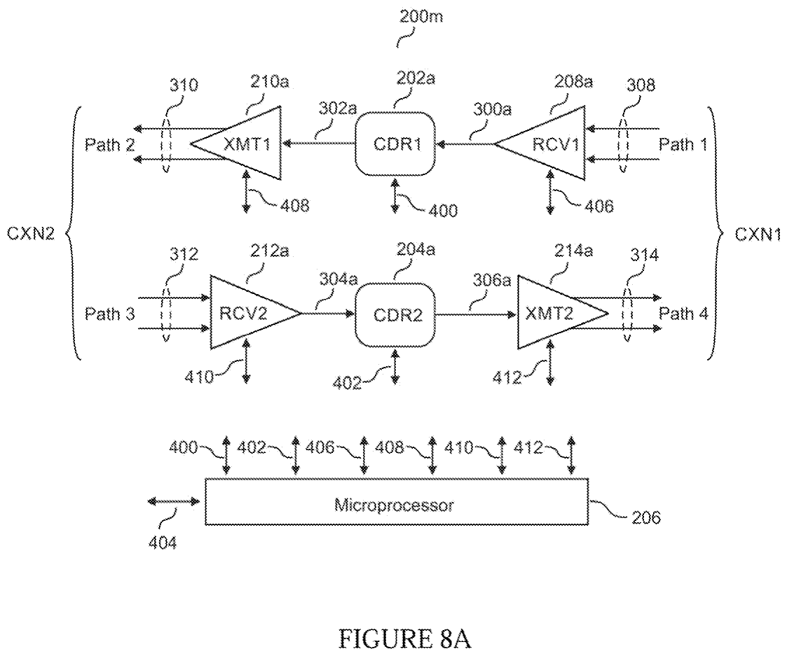

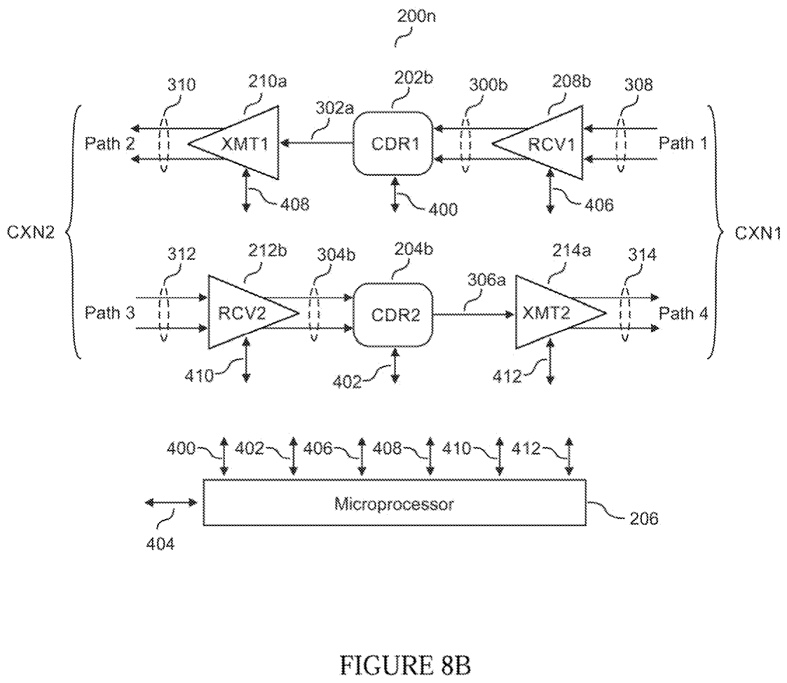

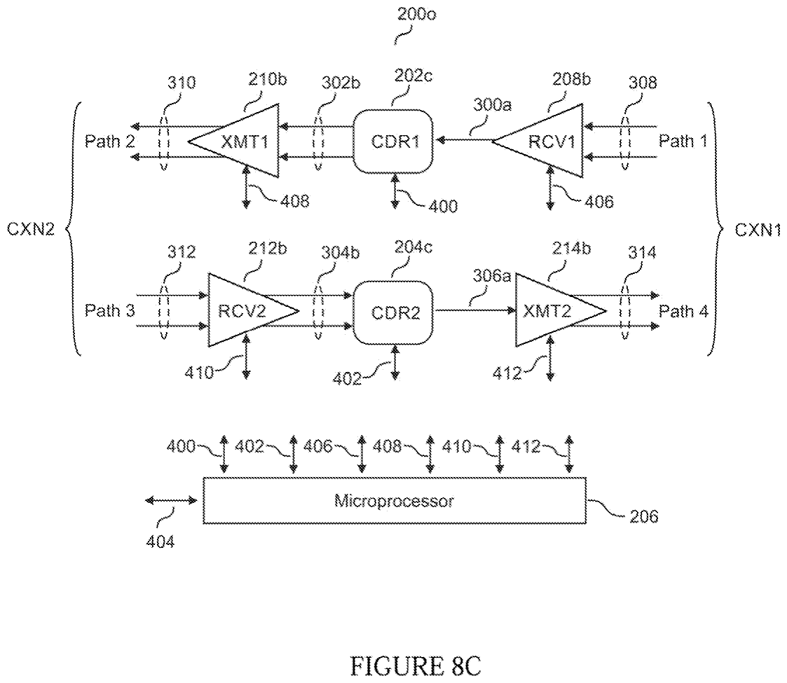

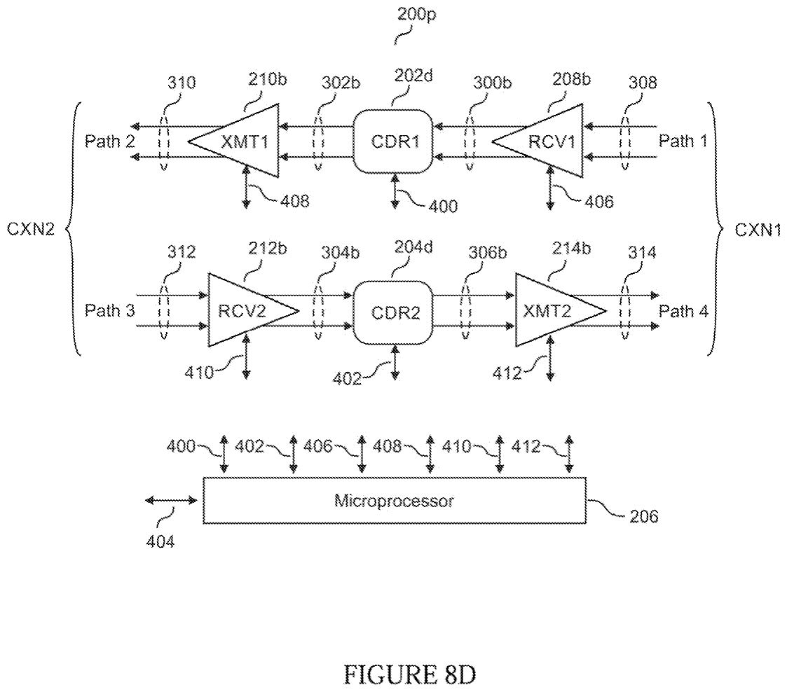

### FIG. 8A-8D (Fourth Embodiment)

In the circuitry, system(s), method(s), equipment ardor device(s) of the present disclosure, the fourth embodiment as illustrated in FIGS. 8A-8D represent a group of related block diagrams versions 200m-200p of the circuitry of the present disclosure involving two connections; CXN1 and CXN2 and two signal paths each. CXN1 has two signal paths, Path 1 and Path 4. CXN2 has two signal paths, Path 2 and Path 3. Each version is comprised of two clock and data recovery circuitries (CDR), a microprocessor circuitry (MPU), two receive circuitries (RCV), and two transmit circuitries (XMT).

FIG. 8A illustrates the version 200m of the third embodiment of the present disclosure comprising clock data recovery circuitry CDR1 202a and CDR2 204a, receive circuitry RCV1 208a and 212a, and transmit circuitry XMT1 210a and XMT2 214a, and a microprocessor circuitry MPU 206. CAN1 comprises a Path 1 representing an input differential signal 308 and a Path 4 representing an output differential signal 314. CXN2 comprises a Path 2 representing an output differential signal 310 and a Path 3 representing an input differential signal 312.

Path 1 (Version 200m) input differential signal 308 connects to the input of RCV1 208a. Receive circuitry RCV1 208a outputs a signal-ended signal 300a to the input CDR1 202a.

Path 2 (Version 200m) output differential signal 310 connects to the output of XMT1 210a. Transmit circuitry XMT1 input single-ended signal 302a connects to the output of CDR1 202a.

Path 3 (Version 200m) input differential signal 312 connects to the input of RCV2 212a. Receive circuitry RCV2 212a outputs a single-ended signal 304a to the input of CDR2 204a.

Path 4 (Version 200m) output differential signal 314 connects to the output of XMT2 214a. Transmit circuitry 214a input single-ended signal 306a connects to the output of CDR2 204a.

FIG. 8B illustrates the version 200n of the third embodiment of the present disclosure comprising clock data recovery circuitry CDR1 202b and CDR2 204b, receive circuitry RCV1 208b and 212b, and transmit circuitry XMT1 210a and XMT2 214a, and a microprocessor circuitry MPU 206. CXN1 comprises a Path 1 representing an input differential signal 308 and a Path 4 representing an output differential signal 314. CXN2 comprises a Path 2 representing an output differential signal 310 and a Path 3 representing an input differential signal 312.

Path 1 (Version 200n) input differential signal 308 connects to the input of RCV1 208b. Receive circuitry RCV1 208b outputs a differential signal 300b to the input CDR1 202b.

Path 2 (Version 200n) output differential signal 310 connects to the output of XMT1 210a. Transmit circuitry XMT1 210a input single-ended signal 302a connects to the output of CDR1 202b.

Path 3 (Version 200n) input differential signal 312 connects to the input of RCV2 212b. Receive circuitry RCV2 212b outputs a differential signal 304b to the input of CDR2 204b.

Path 4 (Version 200m) output differential signal 314 connects to the output of XMT2 214a. Transmit circuitry 214a input single-ended signal 306a connects to the output of CDR2 204b.

FIG. 8C illustrates the version 200o of the third embodiment of the present disclosure comprising clock data recovery circuitry CDR1 202c and CDR2 204c, receive circuitry RCV1 208b and 212b, and transmit circuitry XMT1 210b and XMT2 214b, and a microprocessor circuitry MPU 206. CXN1 comprises a Path 1 representing an input differential signal 308 and a Path 4 representing an output differential signal 314. CXN2 comprises a Path 2 representing an output differential signal 310 and a Path 3 representing an input differential signal 312.

Path 1 (Version 200o) input differential signal 308 connects to the input of RCV1 208b. Receive circuitry RCV 208b outputs a single-ended signal 300a to the input. CDR1 202c.

Path 2 (Version 200o) output differential signal 310 connects to the output of XMT1 210b. Transmit circuitry XMT1 210b input differential signal 302b connects to the output of CDR1 202c.

Path 3 (Version 200o) input differential signal 312 connects to the input of RCV2 212b. Receive circuitry RCV2 212b outputs a differential signal 304b to the input of CDR2 204c.

Path 4 (Version 200o) output differential signal 314 connects to the output of XMT2 214b. Transmit circuitry XMT2 214b input single-ended signal 306a connects to the output of CDR2 204c.

FIG. 8D illustrates the version 200p of the third embodiment of the present disclosure comprising clock data recovery circuitry CDR1 202d and CDR2 204d, receive circuitry RCV1 208b and 212b, and transmit circuitry XMT1 210b and XMT2 214b, and a microprocessor circuitry MPU 206. CXN1 comprises a Path 1 representing an input differential signal 308 and a Path 4 representing an output differential signal 314. CXN2 comprises a Path 2 representing an output differential signal 310 and a Path 3 representing an input differential signal 312.

Path 1 (Version 200p) input differential signal 308 connects to the input of RCV1 208b. Receive circuitry RCV1 208b outputs a differential signal 300b to the input CDR1 202d.

Path 2 (Version 200p) output differential signal 310 connects to the output of XMT1 210b. Transmit circuitry XMT1 210b input differential signal 302b connects to the output of CDR1 202d.

Path 3 (Version 200p) input differential signal 312 connects to the input of RCV2 212b. Receive circuitry RCV2 212b outputs a differential signal 304b to the input of CDR2 204d.

Path 4 (Version 200p) output differential signal 314 connects to the output of XMT2 214b. Transmit circuitry XMT2 214b input differential signal 306b connects to the output of CDR2 204d.

A microprocessor circuitry (MPU) 206 connects to CDR1 202a-202d, CDR2 204a-204d, RCV1 208a-208b, RCV2 212a-212b, XMT1 210a-210d , and XMT2 214a-214b through connections 400, 402, 406, 410, 408, and 412 respectively. MPU 206 interfaces CDR1 202a-202d through connection 400 and CDR2 204a-204d through connection 402. MPU 206 communicates a series of commands to CDR1 202a-202d and CDR2 204a-204d for and provisioning communication bit rate settings, signal output patterns and control, and to determine CDRs performance and status. The MPU 206 will determine performance and status by reading the CDR1 202a-202d and CDR2 204a-204d software registers or by sensing a voltage level from the CDR1 202a-202d and CDR2 204a-204d circuitry pin connectors. MPU 206 may also provision CDR1 202a-202d and CDR2 204a-204d to output a signal with a specific pattern or disable the output to minimize signal noise or corrupted, data to affect other circuitry, systems, and the network during the version initialization or operation, Depending upon the application, MPU 206 can communicate initialization and provisioning settings to RCV1 208a-208b and RCV2 212a-212b. The MPU 206 may provision RCV1 208a-208b and/or RCV2 212a-212b with different amplification and equalization settings. If RCV 208a-208b and RCV2 212a-212b is a buffer or an amplifier with a fixed gain setting, connection 406 and 410 to MPU 206 may not be required. Furthermore, the MPU 206 may request and received performance and operational status of RCV1 208a-208b and RCV2 212a-212b. Depending upon the application, MPU 206 can communicate initialization and provisioning settings to XMT1 210a-210b and XMT2 214a-214b. The MPU 206 may provision XMT1 210a-210b and/or XMT2 214a-214b with amplification, modulation, reformatting, or pre-equalization setting to interface the differential signal connections of 310 and 314.

When a communication signal 308 is present on Path 1 of connection CXN1, RCV1 208a-208b will buffer or amplify the communication signal. RCV1 208a-208b may also equalize the communication signal 308 to remove any signal impairments and/or convert the differential communication signal to a non-differential communication signal to interface CDR1 202a-202d. CDR1 202a-202d will attempt to align and lock to the communication signal bit rate. If CDR1 202a-202d does not align and lock to the communication signal bit rate from connection 300a-300b. CDR1 202a-202d will indicate a non-locked status to the microprocessor (MPU) 206 through connection 400. The MPU 206 will communicate the CDR1 202a-202d non-locked status to supervisory circuitry through connection 404. The microprocessor (MPU) 206 will then provision the CDR1 202a-202d with the next sequential bit rate setting from the communication signal bit rate list. The CDR1 202a-202d will attempt again to align and lock to the communication signal bit rate from connection 300a-300b. If the CDR1 202a-202d does not align and lock to the communication signal bit rate, the process and interactions between the CDR1 202a-202d and the MPU 206 will repeat using the next sequential hit rate setting. If the CDR1 202a-202d aligns and locks to the communication signal bit rate, CDR1 202a-202d will indicate a locked status for MPU 206 through connection 400. The CDR1 202a-202d will re-clock and regenerate the communication signal to interface XMT1 210a-210b through connection 302a-302b. XMT1 210a-210b may perform signal amplification, buffering, format conversion, or conditioning on Path 2 of connection CXN2. The CDR1 202a-202d will also output a message to MPU 206 that CDR1 202a-202d is locked. The MPU 206 will process and store the CDR1 202a-202d locked status and the communication signal bit rate setting. The MPU 206 will communicate the CDR1 202a-202d locked status to supervisory circuitry through connection 404. The MPU 206 will then automatically provision CDR2 204a-204d with the CDR1 202a-202d locked communication signal bit rate settings and any applicable activation or initialization settings. RCV2 212a-212b will equalize the communication signal 312 to remove any signal impairments from connection 312. RCV2 212a will then convert the differential communication signal 312 to a non-differential communication signal 304a to CDR2 204a, while RCV2 212b will then convert the differential communication signal 312 to a differential communication signal 304b to CDR2 204a. CDR2 204a-204b will then align and lock to the communication signal hit rate from connection 304a-304b, CDR2 204a-204d will re-clock and regenerate the locked communication signal 306a-306b to XMT2 214a-214b, XMT2 214a-214b may perform signal amplification, buffering, format conversion, or conditioning on Path 4 of connection CXN1.

The processes and interactions describing the communication signal bit rate auto-alignment of among CDR1 202a-202d, CDR2 204a-204d, and MPU 206 are further discussed and illustrated in FIGS. 13 1.,

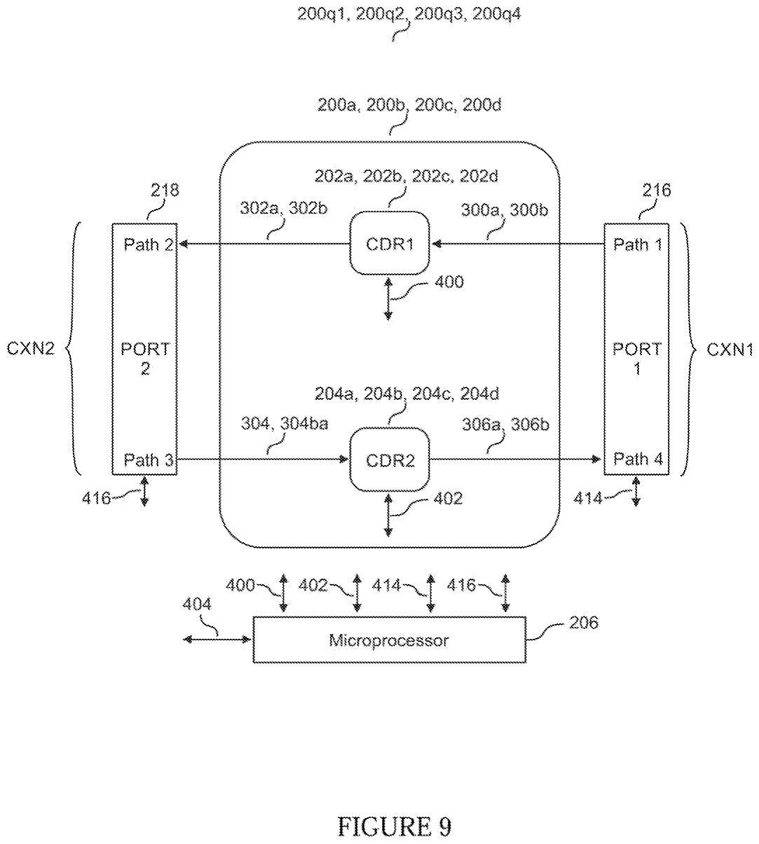

### FIG. 9 (Fifth Embodiment)

In the circuitry, system(s), method(s), equipment and/or device(s) of the present disclosure, the fifth embodiment as illustrated in FIG. 9 represents a group of related embodiment versions 200q1-200q4 of the circuitry of the present disclosure involving two connections; CXN1 and CXN2 and two signal paths each. CXN1 has two signal paths, Path 1 and Path 4. CXN2 has two signal paths, Path 2 and Path 3. Each version is comprised of two clock and data recovery circuitries (CDR), a microprocessor circuitry (MPU), and two ports (PORT).

A port (PORT) is defined as a communication signal and management interface to any component, module, device or equipment with tunable wavelength functionality, clock and data recovery circuitry, or both. A port (PORT) is at least one management interface addressing at least one communication signal interface. Component can be an optical tunable laser, fixed wavelength lasers, tunable ROSA, tunable TOSA, tunable wavelength filter, optical modulator, wavelength locker, waveguides, phase/symbol detector, CDR, tunable antenna, tunable bandpass filters, or wireless MEM. Modules can be an on-board or co-packaged packaged optics such as modules defined by various standards such as the COBO 8-Lane and 16-Lane On-Board Optics Specification, Release 1.1, Dec. 9, 2018, 3.2 Tb/s Copackaged Optics Optical Module, Version 1.0, Feb. 5, 2021, Co-Packaging Framework Document, OIF-Co-Packaging-FD-01.0, Feb. 3, 2022, and/or manufacturers proprietary specifications involving tunable wavelength and CDR functionality. Communication equipment can be communication convergence systems, communication transport systems, data center equipment, communication servers, communication testing and monitoring equipment, passive optical network equipment (OLT and ONU), edge access system equipment, routers, switches, media converters, panels, splitters, and other communication equipment used within the communication networks.

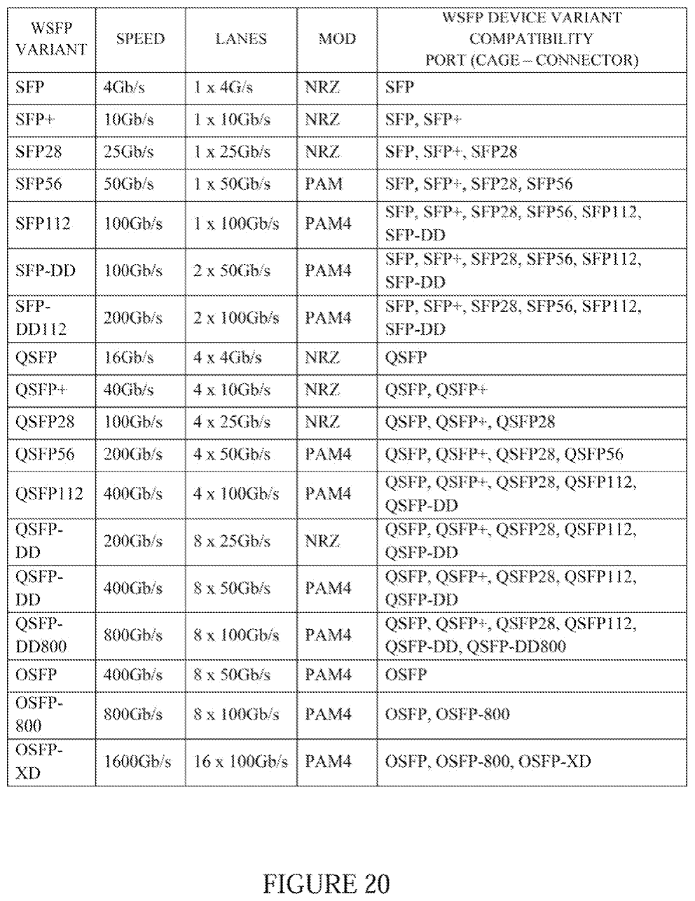

Device is any pluggable device, such as small form-factor pluggable (SFP) variant devices. These SFP variant devices interface communication equipment and networks through wired cables, coax cables, fiber optic cables, or wireless signals. SFP variant devices are defined as SFP, SFP+, SFP28, SFP56, SFP-DD, SFP-DD112, QSFP, QSFP+, QSFP28, QSFP-DD, QSFP-DD800, OSFP, OSFP800, and other future variants. These SFP variant devices can be a single or multiple channel or lane operation for each direction. An SFP variant device with wavelength tuning functions is used to align or tune to the receiving communication signal wavelength and transmit the same or different received communication signal wavelength. This type of SFP variant device with wavelength tuning functionality is typically referred as a tunable SFP+, tunable QSFP+, and future variants such as a tunable SFP-DD, QSFP-DD, OSFP, OSFP-DD, and other SFP variants. An SFP variant device with CDR functions can be used to align or tune to the receiving, port (PORT), comprised of an SFP cage (housing) and device connector, when SFP variant devices are used. The SFP cage and device connector must be compatible with the SFP variant device operation. FIG. 20 is a table illustrating SFP connections recommended backward compatibility with SFP devices operating at rated or maximum speed. A SFP28 CXN can accommodate a SFP28, SFP+ and SFP devices. A SFP28 CXN may accommodate a SFP56 SFP112 devices operating at the 25 Gb/s or 10 Gb/s, but the SIP 28 CXN will not support the SFP56 and SFP112 devices operating at 50 Gb/s and 100 Gb/s, respectively. The SFP28 CXN was not designed to operate at higher speeds whose signal spectral density is higher than the SFP28 CNN's ability. The SFP28 CXN will introduce signal impairments to the communication signal when STP56 and SEP112 devices are operating at their maximum or nominal rate. In the future, SFP56, SFP112, and other newer variants may intemperate with lower rated SFP CXNs using higher signal modulations such as PAM8 and PAM16 and SFP devices with lower power dissipation, the higher signal modulation allows the signal spectral density content to be lower than a non-return to zero (NRZ) signal modulation at the same bit rate. In other words SFP56 devices with PAM4 modulation will have the ability to operate in a SFP28 CXN. SFP Devices in this embodiment can provide different media interfaces such as RJ45, Coax, SC, LC, Duplex LC, MPO-12, SN-Dual, MDC-Dual, and PCB traces. The multi-wave fiber optic and fiber X CXNs in this embodiment are defined as having an SC, LC. Duplex LC. MPO-12, SN-Dual, or MDC-Dual connector.

Management interface is defined as any synchronous, asynchronous, parallel, low-level control leads, or proprietary management interface. Examples of manage interface are I2C, SPI, PCIe, Ethernet, USB, Fiber Channel, RS232, RS485, CAN, and control leads. The microprocessor circuitry (MPU) will communicate with the component, device, module, or equipment management interface for information, status, and provisioning of the component, device, module, or equipment and the communication signal(s).

Embodiment 200q1 of the fifth embodiment version 1 of the present disclosure is comprised of clock data recovery circuitry CDR1 202a and CDR2 204a, a microprocessor circuitry MPU 206, and ports PORT1 216 and PORT2 218. CXN1 comprises a Path 1 representing an input single-ended signal 300a and a Path 4 representing an output single-ended signal 306a. CXN2 comprises a Path 2 representing an output single-ended signal 302a and a Path 3 representing an input single-ended signal 304a. Path 1-Path 4 descriptions are illustrated and described in FIG. 5a, embodiment 200a.

Embodiment 200q2 of the fifth embodiment, version 2 of the present disclosure is comprised of clock data recovery circuitry CDR1 202b and CDR2 204b, a microprocessor circuitry MPU 206, and ports PORT1 216 and PORT2 218. CXN1 comprises a Path 1 representing an input differential signal 300b and a Path 4 representing an output single-ended signal 306a. CXN2 comprises a Path 2 representing, an output single-ended signal 302a and a Path 3 representing an input differential signal 304b. Path 1-Path 4 descriptions are illustrated and described in FIG. 5b, embodiment 200b.

Embodiment 200q3 of the fifth embodiment, version 3 of the present disclosure is comprised of clock data recovery circuitry CDR1 202c and CDR2 204c, a microprocessor circuitry MPU 206, and ports PORT1 216 and PORT2 218. CXN1 comprises a Path 1 representing an input single-ended signal 300a and a Path 4 representing an output differential signal 306b. CXN2 comprises a Path 2 representing an output differential signal 302b and a Path 3 representing an input single ended signal 304a. Path 1-Path 4 descriptions are illustrated and described in FIG. 5c, embodiment 200c.

Embodiment 200q4 of the fifth embodiment, version 4 of the present disclosure is comprised of clock data recovery circuitry CDR1 202d and CDR2 204d, a microprocessor circuitry MPU 206, and ports PORT1 216 and PORT2 218. CXN1 comprises a Path 1 representing an input differential signal 300b and a Path 4 representing an output differential signal 306b. CXN2 comprises a Path 2 representing an output differential signal 302b and a Path 3 representing an input differential signal 304b. Path 1-Path 4 descriptions are illustrated and described in FIG. 5d, embodiment 200d.

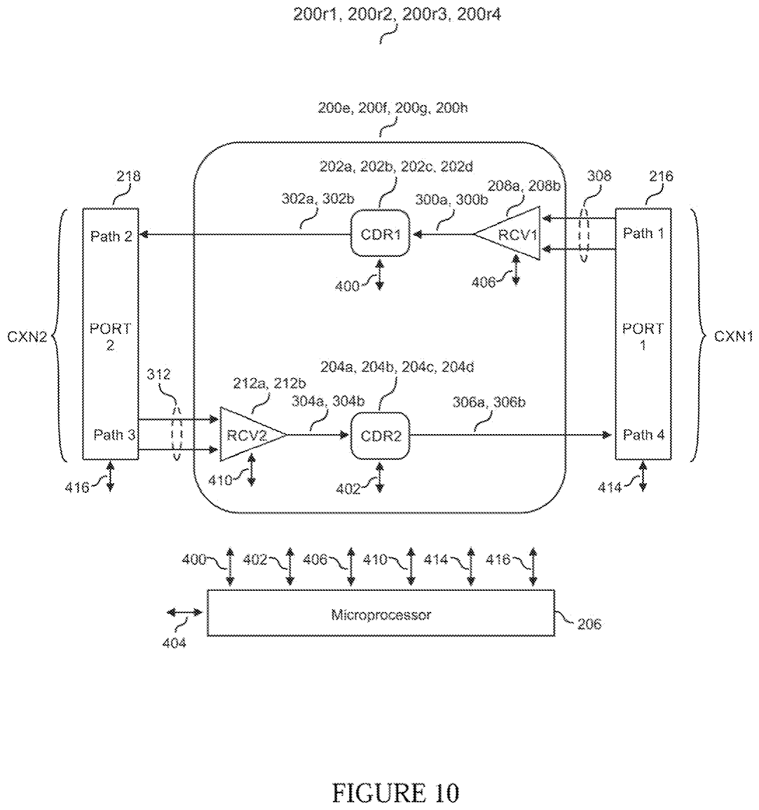

### FIG. 10 (Sixth Embodiment)

In the circuitry, system(s), method(s), equipment and/or device(s) of the present disclosure, the fifth embodiment as illustrated in FIG. 10 represents a group of related embodiment versions 200r1-200r4 of the circuitry of the present disclosure involving two connections; CXN1 and CXN2 and two signal paths each, CXN1 has two signal paths, Path 1 and Path 4. CXN2 has two signal paths, Path 2 and Path 3. Each version is comprised of two clock and data recovery circuitries CDR, a microprocessor circuitry (MPU), two receive circuitries (RCV), and two ports (PORT).

Embodiment 200r1 of the fifth embodiment, version 1 of the present disclosure is comprised of clock data recovery circuitry CDR1 202a and CDR2 204a, receive circuitry RCV1 208a and RCV2 212a, a microprocessor circuitry MPU 206, and ports PORT1 216 and PORT2 218. CXN1 comprises a Path 1 representing an input differential signal 308 going to the input of RCV1 208a, which outputs a single-ended signal 300a going to the input of CDR1 202a, and a Path 4 representing an output single-ended signal 306a. CXN2 comprises a Path 2 representing an output single-ended signal 302a and a Path 3 representing an input differential signal 312 going to the input of RCV2 212a, which outputs a single-ended signal 304a going to the input of CDR2 204a. Path 1-Path 4 descriptions are illustrated and described in FIG. 6a, embodiment 200e.

Embodiment 200r2 of the fifth embodiment, version 2 of the present disclosure is comprised of clock data recovery circuitry CDR1 202b and CDR2 204b, receive circuitry RCV1 208b and RCV2 212b, a microprocessor circuitry MPU 206, and ports PORT1 216 and PORT2 218. CXN1 comprises a Path 1 representing an input differential signal 308 going to the input of RCV1 208b, which outputs a differential signal 300b going to the input of CDR1 202b, and a Path 4 representing an output single-ended signal 306a. CXN2 comprises a Path 2 representing an output single-ended signal 302a and a Path 3 representing an input differential signal 312 going to the input of RCV2 212b, which outputs a differential signal 304b going to the input of CDR2 204b. Path 1-Path 4 descriptions are illustrated and described in FIG. 6b, embodiment 200f.

Embodiment 200r3 of the fifth embodiment, eversion 3 of the present disclosure is comprised of clock data recovery circuitry CDR1 202c and CDR2 204c, receive circuitry RCV1 208a and RCV2 212a, a microprocessor circuitry MPU 206, and ports PORT 216 and PORT2 218. CXN1 comprises a Path 1 representing an input differential signal 308 going to the input of RCV1 208a, which outputs a single-ended signal 300a going to the input of CDR1 202c, and a Path 4 representing an output differential signal 306b. CXN2 comprises a Path 2 representing an output differential signal 302b and a Path 3 representing an input differential signal 312 going to the input of RCV2 212a, which outputs a single-ended signal 304a going to the input of CDR2 204c. Path 1-Path 4 descriptions are illustrated and described in FIG. 6c, embodiment 200g.

Embodiment 200r4 of the fifth embodiment, version 4 of the present disclosure is comprised of clock data recovery circuitry CDR1 202d and CDR2 204d, receive circuitry RCV1 208b and RCV2 212b, a microprocessor circuitry MPU 206, and ports PORT1 216 and PORT2 218. CXN1 comprises a Path 1 representing an input differential signal 308 going to the input of RCV1 208b, which outputs a differential signal 300b going to the input of CDR1 202d, and a Path 4 representing an output differential signal 306b. CXN2 comprises a Path 2 representing an output differential signal 302b and a Path 3 representing an input differential signal 312 going to the input of RCV2 212b, which outputs a differential signal 304b going to the input of CDR2 204d. Path 1-Path 4 descriptions are illustrated and described in FIG. 6d, embodiment 200h.

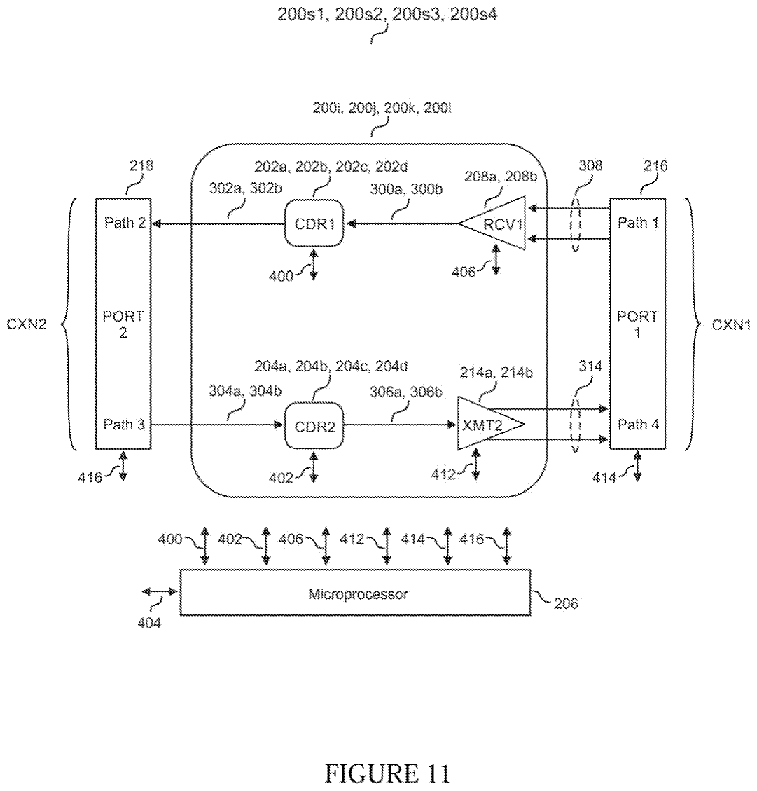

### FIG. 11 (Seventh Embodiment)

In the circuitry, system(s), method(s), equipment and/or device(s) of the present disclosure, the sixth embodiment as illustrated in FIG. 11 represents a group of related embodiment versions 200s1-200s4 of the circuitry of the present disclosure involving two connections, CXN1 and CXN2 and two signal paths each. CXN1 has two signal paths, Path 1 and Path 4. CXN2 has two signal paths, Path 2 and Path 3. Each version is comprised of two clock and data recovery circuitries (CDR), a microprocessor circuitry (MPU), a receive circuitry (RCN), a transmit circuitry (XMT), and two ports (PORT).

Embodiment 200s1 of the sixth embodiment version 1 of the present disclosure is comprised of clock data recovery circuitry CDR1 202a and CDR2 204a, a receive circuitry RCV1 208a, a transmit circuitry XMT2 214a, a microprocessor circuitry MPU 206, and ports PORT1 216 and PORT2 218. CXN1 comprises a Path 1 representing an input differential signal 308 going to the input of RCV1 208a, which outputs a single-ended signal 300a going to the input of CDR1 202a, and a Path 4 representing an output differential signal 314 from the output of XMT2 214a, which receives a single-ended signal 306a from the output of CDR2 204a, CXN2 comprises a Path 2 representing an output single-ended signal 302a and a Path 3 representing an input single-ended signal 304a. Path 1-Path 4 descriptions are illustrated and described in FIG. 7a, embodiment 200i.

Embodiment 200s2 of the sixth embodiment, version 2 of the present disclosure is comprised of clock data recovery circuitry CDR1 202b and CDR2 204b, a receive circuitry RCV1 208b, a transmit circuitry XMT2 214b, a microprocessor circuitry MPU 206, and ports PORT1 216 and PORT2 218. CXN1 comprises a Path 1 representing an input differential signal 308 going to the input of RCV1 208a, which outputs a differential signal 300b going to the input of CDR1 202a, and a Path 4 representing an output differential signal 314 from the output of XMT2 214b, which receives a differential signal 306b from the output of CDR2 204b. CXN2 comprises a Path 2 representing an output single-ended signal 302a and a Path 3 representing an input single-ended signal 304a. Path 1-Path 4 descriptions are illustrated and described in FIG. 7b, embodiment 200j.

Embodiment 200s3 of the sixth embodiment, version 3 of the present disclosure is comprised of clock data recovery circuitry CDR1 202c and CDR2 204c, a receive circuitry RCV1 208a, a transmit circuitry XMT2 214a, a microprocessor circuitry MPU 206, and ports PORT1 216 and PORT2 218. CXN1 comprises a Path 1 representing an input differential signal 308 going to the input of RCV1 208a, which outputs a single-ended signal 300a going to the input of CDR1 202c, and a Path 4 representing an output differential signal 314 from the output of XMT2 214a, which receives a single-ended signal 306a from the, output of CDR2 204c. CXN2 comprises a Path 2 representing an output differential 302b and a Path 3 representing an input differential signal 304b. Path 1-Path 4 descriptions are illustrated and described in FIG. 7c, embodiment 200k.

Embodiment 200s4 of the sixth embodiment, version 4 of the present disclosure is comprised of clock data recovery circuitry CDR1 202d and CDR2 204d, a receive circuitry RCV1 208b, a transmit circuitry XMT2 214b, a microprocessor circuitry MPU 206, and ports PORT1 216 and PORT2 218. CXN1 comprises a Path 1 representing an input differential signal 308 going to the input of RCV1 208b, which outputs a differential signal 300b going to the input of CDR1 202d, and a Path 4 representing an output differential signal 314 from the output of XMT2 214b, which receives a differential signal 306b from the output of CDR2 204d. CXN2 comprises a Path 2 representing an output differential signal 302b and a Path 3 representing an input differential signal 304b. Path 1-Path 4 descriptions are illustrated and described in FIG. 7d, embodiment 200l.

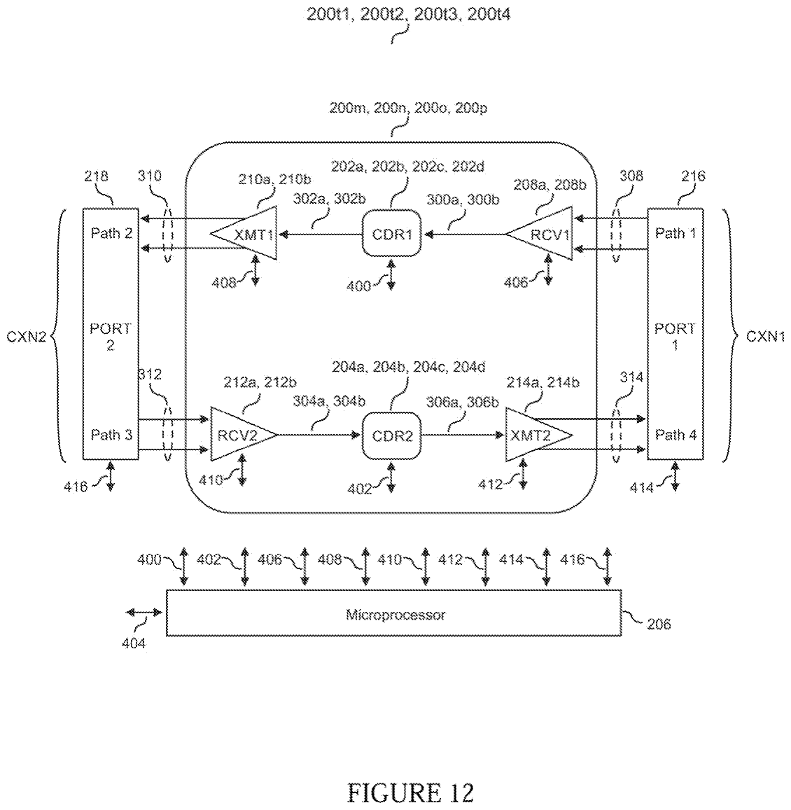

### FIG. 12 (Eighth Embodiment)

In the circuitry, system(s), method(s), equipment and/or device(s) of the present disclosure, the seventh embodiment as illustrated in FIG. 12 represents a group of related embodiment versions 200t1-200t4 of the circuitry of the present disclosure involving two connections; CXN1 and CXN2 and two signal paths each. CXN1 has two signal paths, Path 1 and Path 4. CXN2 has two signal paths, Path 2 and Path 3. Each version is comprised of two clock and data recovery circuitries (CDR), a microprocessor circuitry (MPU), two receive circuitries (RCV), two transmit circuitries (XMT), and two ports (PORT).

Embodiment 200t1 of the seventh embodiment, version 1 of the present disclosure is comprised of clock data recovery circuitry CDR1 202a and CDR2 204a, receiver circuitry RCV1 208a and 212a, and transmit circuitry XMT2 210a and XMT2 214a, a microprocessor circuitry MPU 206, and ports PORT1 216 and PORT2 218. CXN1 comprises a Path 1 representing an input differential signal 308 going to the input of RCV1 208a, which outputs a single-ended signal 300a going to the input of CDR1 202a, and a Path 4 representing an output differential signal 314 from the output of XMT2 214a, which receives a single-ended signal 306a from the output of CDR2 204a. CXN2 comprises a Path 2 representing an output differential signal 310 from the output of XMT1 210a, which receives a single-ended signal 302a from the output of CDR1 202a, and a Path 3 representing, an input differential signal 312 going to the input of RCV2 212a, which outputs a single-ended signal 304a going to the input of CDR2 204a. Path Path 4 descriptions are illustrated and described in FIG. 8a, embodiment 200m.

Embodiment 200t2 of the seventh embodiment, version of the present disclosure is comprised of clock data recovery circuitry CDR1 202b and CDR2 204b, receiver circuitry RCV1 208b and 212b, and transmit circuitry XMT1 210a and XMT2 214a, a microprocessor circuitry MPU 206, and ports PORT1 216 and PORT2 218. CXN1 comprises a Path 1 representing an input differential signal 308 going to the input of RCV1 208b, which outputs a differential signal 300b going to the input of CDR1 202b, and a Path 4 representing an output differential signal 314 from the output of XMT2 214a, which receives a single-ended signal 306a from the output of CDR2 204b. CXN2 comprises a Path 2 representing an output differential signal 310 from the output of XMT1 210a, which receives a single-ended signal 302a from the output of CDR1 202b, and a Path 3 representing an input differential signal 312 going to the input of RCV2 212b, which outputs a differential signal 304b going to the input of CDR2 204b, Path 1-Path 4 descriptions are illustrated and described in FIG. 8b, embodiment 200n.

Embodiment 200t3 of the seventh embodiment, version 3 of the present disclosure is comprised of clock data recovery circuitry CDR1 202c and CDR2 204c, receiver circuitry RCV1 208b and 212b, and transmit circuitry XMT1 210b and XMT2 214b, a microprocessor circuitry MPU 206, and ports PORT1 216 and PORT2 218, CXN1 comprises a Path 1 representing an input differential signal 308 going to the input of RCV1 208b, which outputs a single-ended signal 300a going to the input of CDR1 202c, and a Path 4 representing an output differential signal 314 from the output of XMT2 214b, which receives a single-ended signal 306a from the output of CDR2 304c. CXN2 comprises a Path 2 representing an output differential signal 310 from the output of XMT1 210b, which receives a differential signal 302b from the output of CDR1 202c, and a Path 3 representing an input differential signal 312 going to the input of RCV2 212b, which outputs a differential signal 304b going to the input of CDR2 204c, Path 1-Path 4 descriptions are illustrated and described in FIG. 8c, embodiment 200n.

Embodiment 200t4 of the seventh embodiment, version 4 of the present disclosure is comprised of clock data recovery, circuitry CDR1 202d and CDR2 204d, receiver circuitry RCV1 208b and 212b, and transmit circuitry XMT1 210b and XMT2 214b, a microprocessor circuitry MPU 206, and ports PORT1 216 and PORT2 218, CXN1 comprises a Path 1 representing an input differential signal 308 going to the input of RCV1 208b, which outputs a differential signal 300b going to the input of RCV1 202d, and a Path 4 representing an output differential signal 314 from the output of XMT2 214b, which receives a differential signal 306b from the output of CDR2 204d. CXN2 comprises a Path 2 representing an output differential signal 310 from the output of XMT1 210b, which receives a differential signal 302b from the output of CDR1 202d, and a Path 3 representing an input differential signal 312 going to the input of RCV2 212b, which outputs a differential signal 304b going to the input of CDR2 204d, Path 1-Path 4 descriptions are illustrated and described in FIG. 8d, embodiment 200p.

### Wavelength Converter (Fifth-Eighth Embodiments)

In the circuitry, system(s), method(s), equipment and/or device(s) of the present disclosure, the embodiments 200q1-200q4, 200r1-200r4, 200s1-200s4, and 200t1-200t4 can convert the communication signal wavelength from connection CXN1 to a different wavelength on connection CXN2 by means of communicating wavelength provisioning to PORT1 216 and/or PORT2 218 by means of the MPU 206 provisioning a change in transmit wavelength to a component, module, device, or equipment with tunable transmit wavelength functionality. A component with an optical modulator, a module, device, or equipment with a tunable transmitter optical subassembly TOSA with the capability to change wavelength per grid spacings or channels. The following standards or agreements provide information and details on transmit and receiving wavelength tuning ITU-T G.694.1 4, 02/2012, Spectral Grids for WDM Applications: DWDM Frequency Grid, SFF-8477, Rev 1.4, Dec. 4, 2009, Specification for Tunable XFP for ITU Frequency Grid Applications, SFF-8690, Rev 1.4. Jan. 23, 2013, Tunable SFP+ Memory Map for ITU Frequencies, Rev 1.4, SFF-TA-1004, Rev 0.0.10 Jan. 23, 2018, Specification for Tunable QSFP+/QSFP28 Memory Map for ITU Frequencies, SFF-8024, Rev 4.9, May 24, 2021, Specification for SFF Module Management Reference Code Tables, SFP-DD MIS Rev 2.0, Sep. 25, 2020, SFP-DD MIS Management Interface Specification for SFP Double Density 2X Pluggable Transceiver, OIF-ITLA-MSA-01.3, Jul. 13, 2015, Integrable Tunable Laser Assembly Multi Source Agreement, OIF-MicroITLA-01.1, Jul. 13, 2015, Micro Integrable Tunable Laser Assembly Implementation Agreement, OIF-TLMSA-01.0 Multi-Source Agreement for CW Tunable Lasers, OIF-CMIS-05.2, Revision 5.2, Apr. 27, 2022, Common Management Interface Specification (CMIS). QSFP-DD Common Management Interface Specification for 8X/16X Pluggable Transceivers, Rev 3.0 Aug. 17, 2018.

### Flow Chart (First-Eighth Embodiments)

FIGS. 13-16 illustrates a group of flow charts and/or table(s) describing the auto-alignment of communication signal bit rate processes and interactions among CDR1 (202a, 202b, 202c, 202d), CDR2 (204a, 204b, 204c, 204d), and MPU 206 of the versions 200a-200p of the present disclosure.

FIG. 13 illustrates a flow chart 500 describing a process to determine, create, and initialize the communication service list for the versions 200a-200p to auto-align to the communication signal hit rates. As was previously discussed, an exemplary list of these: unique high speed communication signals are 10GELAN, 10GEWAN, CPRI7, eCPRI, OC-192 SONET, 10GFC, 16GFC, 28GFC, 32GFC, 64GFC, 128GFC, OTN1e, OTN2, OTN2e, USB3.1, G-PON, GE-PON, 10G-EPON, XG-PON, XGS-PON, NG-PON2, 25GS-PON, 50G-EPON, 50G-GPON 100G/200G GPON, Super-PON and others.

Wavelength division multiplexing (WDM) is a technology used on optical communications to multiplex a number of different wavelength signals onto a single optical fiber cable or strand. WDM is a technology to increase the communication signal transmission bandwidth. There are many different variants, such as coarse wavelength division multiplexing (CWDM), dense wavelength division multiplexing (DWDM), and others. Dense Wavelength Division Multiplexing (DWDM) further increases the communication signal transmission bandwidth by multiplexing a greater number of wavelength signals using different grid spacings 0.4/0.8/1.6 nm (50/100/200 GHz grid), which enable DWDM to multiplex 40, 80, and 160 wavelength channels over a single optical fiber cable. ITU-T G.694.1 4, 02/2012, Spectral Grids for WDM Applications: DWDM Frequency Grid is an international standard on DWDM technologies.

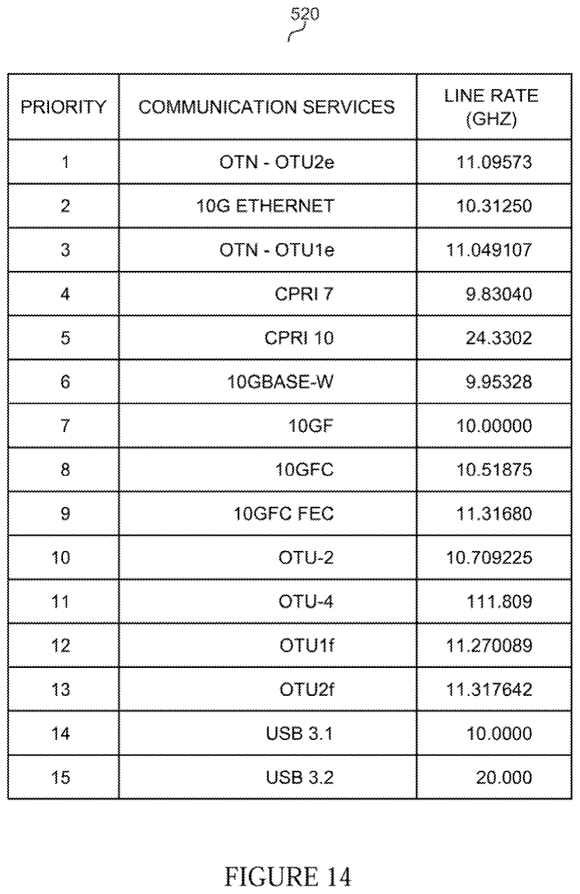

The communication service list is determined at step 502 by the equipment design, end-user application, service provider's network, or a combination thereof. The communication service list can be comprised of communication bits rates, wavelengths, grid spacings, length channels, frequency, and bands. The communication service list can also be composed of vendor information, communication services, technology, service application and many other identifications or classifications from a component, module, device or equipment. The communication service lists are used by the CDR and/or PORTs to automatically align or tune to the communication signal bit rate, wavelength, or both wavelength and bit rate to re-clock or re-time the communication signal. Once the communication service list is established at step 502, the list may require prioritization as determined at step 504. Prioritization of the list may be required if the versions 200a-200p alignment and lock timing must be kept at a minimum. Prioritization of the list will also minimize installation, maintenance, or repair times. Minimizing the alignment or acquisition timing is critical to ensure the overall communication service latency. For example, 5G wireless service networks requires latency of 1 millisecond to ensure the operation of real-time applications. The Service Providers must ensure their 5G wireless service network equipment and infrastructure will meet the 5G latency requirement. If prioritization of the list is required, the flow chart proceeds to step 506 for the update arrangement of the list in the order of communication service application utilization, future application, and usage probability. In this example, the communication service list is comprised of communication service signal bit rates, which represent the communication services, set forth in FIG. 14. If the Service Provider's network is currently supporting OTN2e communication services and the Service Provider's network will be migrating to 10GLAN (i.e., 10GE LAN or 10G ETHERNET), the communication service list table 520, illustrated in FIG. 14, will have OTN2e as the first hit rate setting and 10GLAN as the second bit rate setting. Once the prioritization of list is updated at step 506, or if the list did not need to be prioritized as determined at step 504 wherein step 506 is skipped, the communication service signal bit rate settings are to be determined and calculated for CDR1 202a-202d and CDR2 204a-204d, at step 508. The hit rate settings for CDR1 202a-202d and CDR2 204a-204d are proprietary and unique to each CDR design, methodology, or manufacturer. The final step is the implementation of the list wherein the list is then implemented into the microprocessor 206 or CDR1 202a-202d. and CDR2 204a-204d, at step 510. The microprocessor 206 accesses the list through memory, a machine logic, or from another microprocessor.

FIG. 14 illustrates a table 520 of a communication services list describing signal line rates. The signal line rates represent signal bit rates, which used to calculate and program CDR1 202a-202d and CDR2 204a-204d for embodiments 200a-200p. These programming settings are proprietary and unique to the manufacturer design and implementation of the CDR circuitry. The communication service signal bit rate list is preferably prioritized to minimize the CDR1 202a-202d alignment and lock timing. In this example, the CDR1 202a 202d will be initially aligned to OTN-OTU2e communication service signal bit rate when powering-up, communication service updates or change, signal loss event, SFP device updates, or a combination thereof. If the CDR1 202a-202d does not align and lock to the OTN-OTU2e communication service signal bit rate, the microprocessor MPU 206 will step to the next communication service signal bit rate on the list, 10G Ethernet. MPU 206 will provision CDR1 202a-202d with the 10G Ethernet signal bit rate. The MPU 206 will repeat this process, progressing though the list, if CDR1 202a-202d does not align and lock.

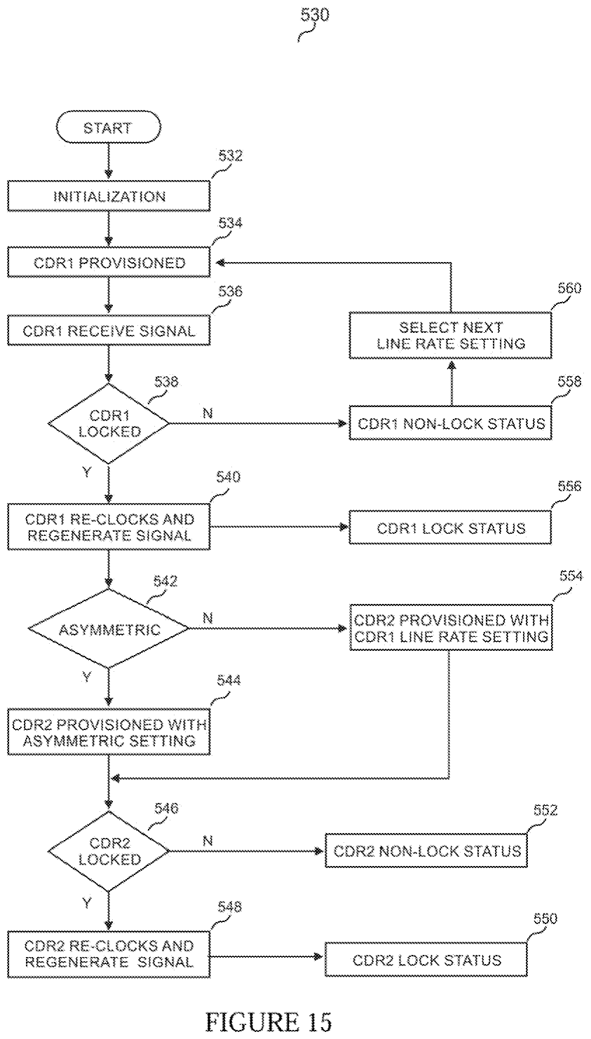

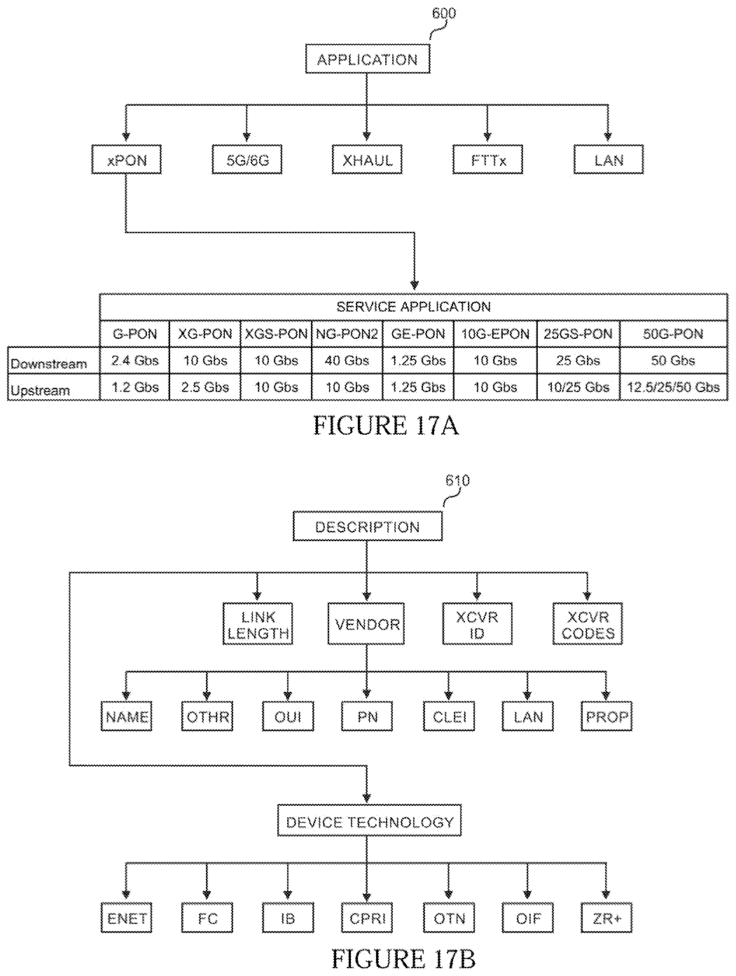

FIG. 15 illustrates a flow chart 530 illustrating the auto-alignment process of versions 200a-200p. The start or initialization step 532 is the versions 200a-200p powering to the nominal operating voltage level and initialization. The microprocessor (MPU) 206 communicates initialization and provisioning settings to the clock data recovery circuitry (CDR) and applicable receive circuitry (RCV), transmit circuitry (XMT), and port (PORT) as illustrated in embodiments 200a-200p. The MPP 206 then selects the signal bit rate setting from the list or prioritize list and provisions CDR1 202a-202d to align with the selected signal bit rate, step 534. When CDR1 202a-202d receives a communication signal, step 536, CDR1 202a-202d will attempt to align and lock to the signal bit rate, step 538. If CDR1 202a-202d does not align, and lock to the signal bit rate, CDR1 202a-202d will provide a non-lock indication status to 206 through connector 400, step 558. The MPU 206 will then select the next signal bit rate settings from the list or prioritize list, step 560. The MPU 206 will then provision CDR1 202a-202d with the next selected communication signal bit rate setting, step 534. CDR1 202a-202d will attempt to align and lock to the signal with the next signal bit rate again, steps 536 and 538. If CDR1 202a-202d aligns and locks to the communication signal bit rate, CDR1 202a-202d will re-clock and regenerate the communication, step 540. CDR1 202a-202d will provide lock indication status to MPU 206 through connection 400, step 556. The MPU 206 will then determine if the communication service has an asymmetric line rate, step 542, by referring to the appropriate communication service list. This communication service list can be a list comprising of vendor, technology, device, communication service, bit-rate, wavelength, or application information. A communication service list comprised of applications will provide information on an asymmetric line rate as associated with variants of passive optical network (xPON) technologies, FIG. 17A. If the communication service does not have an asymmetric line rate, the MPU 206 provisions the CDR2 204a-204d with the CDR1 202a-202c communication signal bit rate setting, step 554.

If the communication service does have an asymmetric line rate, the MPU 206 provisions the CDR2 204a-204d with the asymmetric communication signal bit rate setting, step 544 from the communication service list. At step 546, if CDR2 204a-204d does not align and lock, to the signal, CDR2 204a-204d will provide non-lock indication status to MPU 206 through connection 402, step 552. If CDR2 204a-204d aligns and locks to the communication signal bit rate, CDR2 204a-204d will re-clock and regenerate the signal, step 548. CDR2 204a-204d wilt provide lock indication status to MPU 206 through connection 402 step 550.

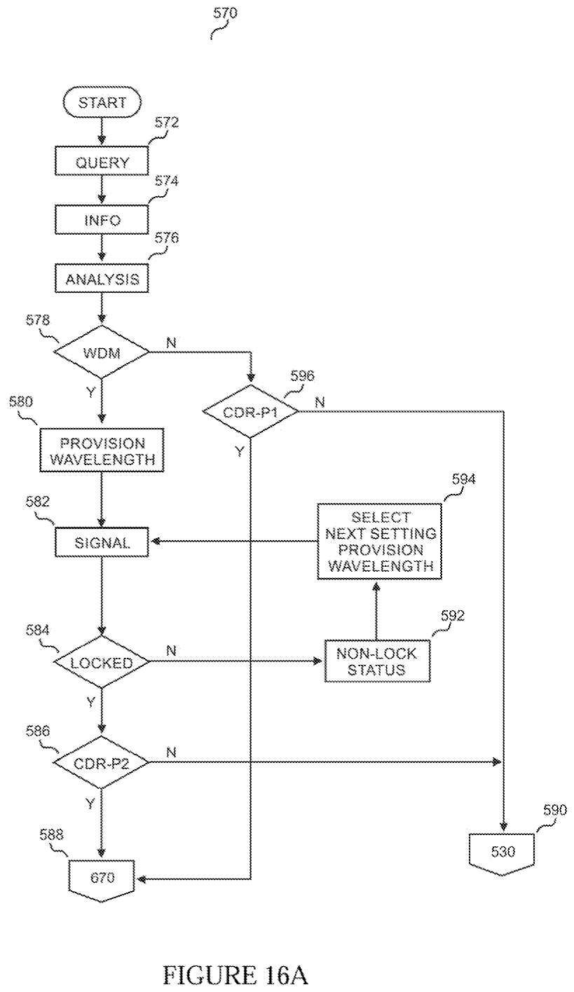

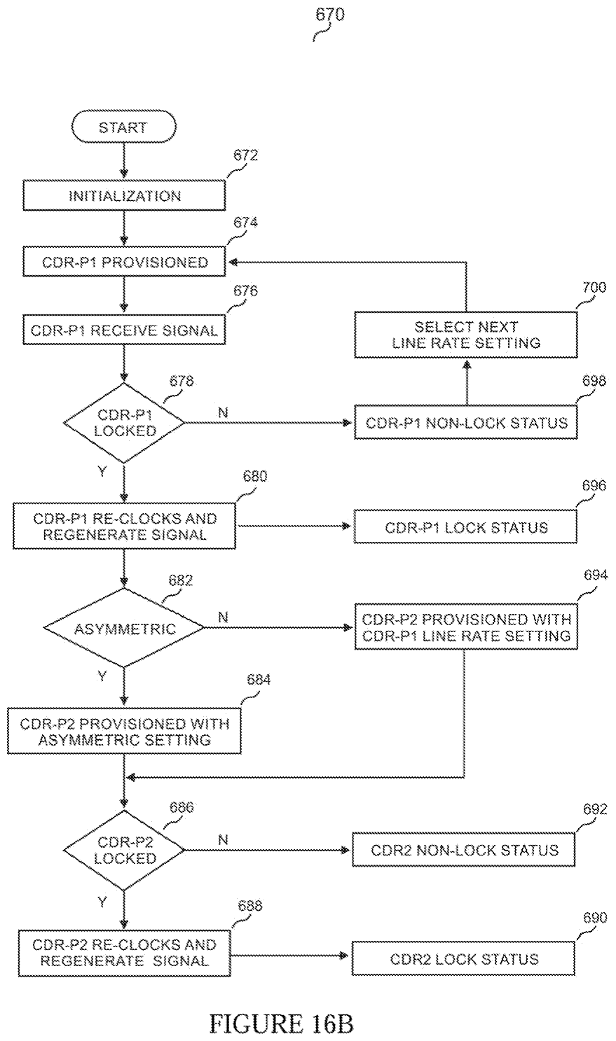

FIG. 16A illustrates a flow chart 570 illustrating the auto-alignment process involving embodiment 200q-200t. Embodiments 200q-200t are respectively comprised of embodiments 200a-200p and two ports PORT 1 and PORT 2. The microprocessor (MPU) 206 communicates or queries the component, module, device, or equipment by means of a management interface, step 572. A management interface is defined as any synchronous asynchronous, parallel, low-level control leads, or proprietary management interface. Examples of manage interface are I2C, SPI, PCIe, Ethernet, USB, Fiber Channel, RS232, RS485, CAN, and control leads. The MPU 206 will retrieve information, step 574, to identify the component, module, device, or equipment description, type, functionality, the communication service, the communication technology, the application, and many other identifications as described in appropriate SFF, OIF, ITU, IEEE standards and agreements to use, create, and/or update a communication service list. FIGS. 17A and 17B illustrates flowcharts categorizing some of the above information received from a component, module, device, or equipment.

The MPU 206 will then analyze the communication service list or information from the component, device, module, or equipment, step 576, to determine at step 578 if the communication service is a wave-division multiplexing technology. If the communication service is a not a wave-division multiplexing technology and the component, module, device, or equipment has clock data and recovery circuitry (CDR-P1) stele 596, the MPU 206 will provision the CDR-P1 using flowchart 670 (FIG. 16B) with the appropriate communication service list or management communication information to auto-align to the communication service bit rate, step 588. If the communication service is a wave-division multiplexing technology, the MPU 206 will provision the component, module, device, or equipment with a receive and transmit wavelength for the communication service using the appropriate communication service list or management communication information, step 580. For example a 9.95328 Gb/s NG-PON2 has a downstream operating wavelength band of 1596-1603 nm and an upstream operating wavelength hand of 1524-1544 nm (wide band option), 1528-1540 nm (reduced band option) or 1532-1540 (narrow band option).

If the MPU 206 receives a signal, step 582 and then a non-lock wavelength status from the management interface of the component, module, device or equipment, at step 584, the MPU 206 will provide a non-lock wavelength indication status to MPU 206 through connection 400, step 592. The MPU 206 will then communicate to the component, module, device, or equipment to select and provision the next wave-division multiplexing wavelength settings, step 594. If the MPU 206 receives a lock wavelength status from the management interface communication with the component, module, device, or equipment, at step 584, then the MPU 206 will determine if the component, module, device, or equipment has clock data and recovery circuitry (CDR-P2), step 586. If the MPU206 determines that the component, module, device, or equipment does not have a CDR-P2, then transition to flowchart 530 illustrated, in FIG. 15, step 590. If the MPU 206 determines that the component, module, device, or equipment does have a CDR-P2, then transition to flowchart 670 illustrated in FIG. 16B, step 588.

FIG. 16B illustrates a flow chart 670 illustrating, an extension of flee chart 570 (FIG. 16A). Flow chart 670 illustrates the auto-alignment process of the component, module, device, or equipment clock and data recovery circuitries CDR-P1 and CDR-P2. The microprocessor (MPU) 206 communicates initialization and provisioning settings to the clock data recovery circuitries CDR-P1 and CDR-P2 with the appropriate communication service list or management communication information step 672. The MPU 206 then selects the signal bit rate setting from the list, prioritize list, or management interface communication information and provisions CDR1-P1 with the selected signal bit rate, step 674. When CDR-P1 receives a communication signal, step 676, CDR-P1 will attempt to align and lock to the signal bit rate, step 678. If CDR-P1 does not align and lock to the signal bit rate, CDR-P1 will provide a non-lock indication status to MPU 206 through connector 400, step 698. The MPU 206 will then select the next signal bit rate settings from the list, prioritize list, management interface communication information, step 700. The MPU 206 will then provision CDR-P1 with the next selected communication signal bit rate setting, step 674. CDR-P1 will attempt to align and lock to the signal with the next signal bit rate again, steps 676 and 678. If CDR-P1 aligns and locks to the communication signal bit rate, CDR-P1 will re-clock and regenerate the communication, step 680. CDR-P1 will provide lock indication status to 206 through connection 400, step 696. The MPU 206 will then determine if the communication service has an asymmetric line rate, step 682, by referring to the appropriate communication service list or management interface communication information. Asymmetric line rates are typically associated with variants of passive optical network (xPON) technologies, FIG. 17A. If the communication service does not have an asymmetric line rate, the MPU 206 provisions the CDR-P2 with the CDR-P1 communication signal bit rate setting, stop 694.

If the communication service does have an asymmetric line rate, the MPU 206 provisions the CDR-P2 with the asymmetric communication signal bit rate setting, step 684 from the communication service list or management interface communication information. At step 686, if CDR-P2 does not align and lock to the signal, CDR-P2 will provide non-lock indication status to MPU 206 through connection 402, step 692. If CDR-P2 aligns and locks to the communication signal bit rate, CDR-P2 will re-clock and regenerate the signal, step 688. CDR-P2 will provide lock indication status to MPU 206 through connection 402, step 690.

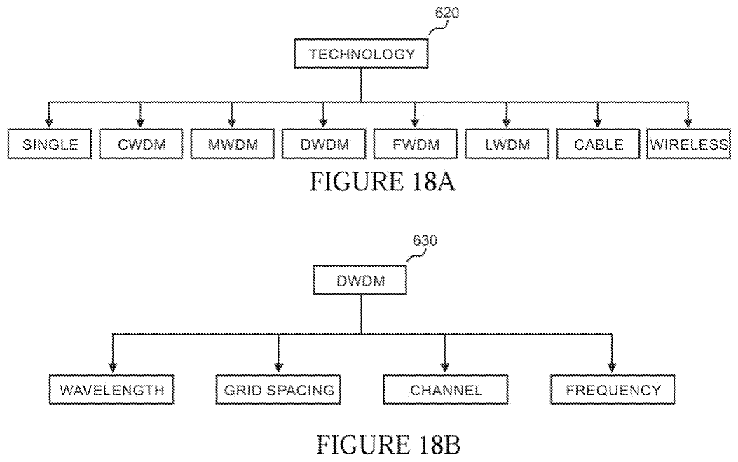

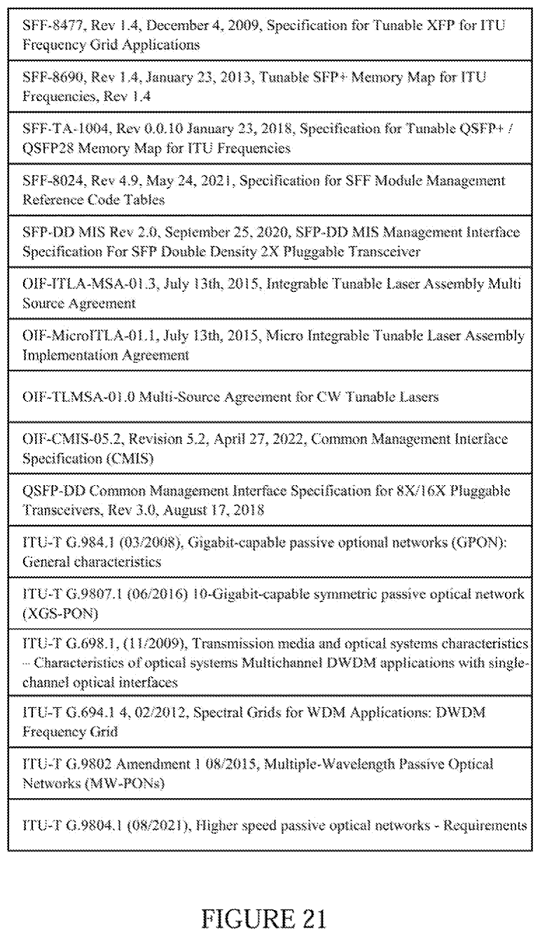

Application classification flowchart 600 and description classification flowchart 610 are illustrated in FIGS. 17A and 17B respectively, and technology classification flowchart 620 and DWDM flowchart 630 are illustrated in FIGS. 18A and 18B respectively. These flowcharts 600-630 are a partial example of information received from a component, module, device, or equipment via the management communication interface. The MPU 206 will communicate the appropriate wave-division multiplexing transmit and/or receive wavelength settings using information from the table in FIG. 21 to the component, module, device, or equipment via the management interface.

FIGS. 17A and 17B illustrate information received from a component, module, device, or equipment via a management interface. In FIG. 17A, Application 600 illustrates different communication service applications of the component, module, device, or equipment. This application 600 flowchart list provides information to identify and assistant in the alignment and/or tuning process.

Passive optical network (PON) is an application technology with many variants, where each variant is defined by IEEE, ITU, DOCSIS and other standards and implementation agreements. xPON variants are G-PON, GE-PON, XG-PON, XGS-PON, NG-PON2, GE-PON, 10G-EPON, 25GS-PON, and 50G-PONs. 5G/WiFi is a wireless application technology. XHAUL is an application technology for Service Providers transport or backbone network. XHAUL technology is comprised of legacy SONET, OTN, to, native Ethernet. FTTx is an optical networking application technology for fiber to the home FTTH, curb FTTC, premises FTTP, building FTTB, and others. FTTx is defined per ITU and IEEE standards. LAN is an application technology involving native Ethernet technologies.

In FIG. 17B, Description 610 illustrates information on component, module, device, or equipment providing the service. Description 610 are defined by various component, module, device, and equipment standards or agreements such as the following.

SFF-8024, Rev 4.9, May 24, 2021, Specification for SFF Module Management Reference Code Tables

SFP-DD MIS Rev 2.0, Sep. 25, 2020, SFP-DD MIS Management Interface Specification for SFP Double Density 2X Pluggable Transceiver

OIF-ITLA-MSA-01.3, Jul. 13, 2015, Integrable Tunable Laser Assembly Multi Source Agreement

OIF-MicroITLA-01.1, Jul. 13, 2015, Micro Integrable Tunable Laser Assembly Implementation Agreement

OIF-TLMSA-01.0 Multi-Source Agreement for CW Tunable Lasers

OIF-CMIS-05.2, Revision 5.2, Apr. 27, 2022, Common Management interface Specification (CMIS)

OSFP-DD Common Management Interface Specification for 8X/16X Pluggable Transceivers, Rev 3.0, Aug. 17, 2018

FIGS. 18A and 18B illustrate other information received from a component, module, device, or equipment via a management interface. In FIG. 18A, Technology 620 illustrates different communication service technologies such as single wave (SW), wave division multiplexing variants (CWDM, MWDM, DWDM, FWDM, LWDM), cable, and wireless. In FIG. 18B, DWDM 630 provides further information to aid in the alignment an for tuning on DWDM technologies.

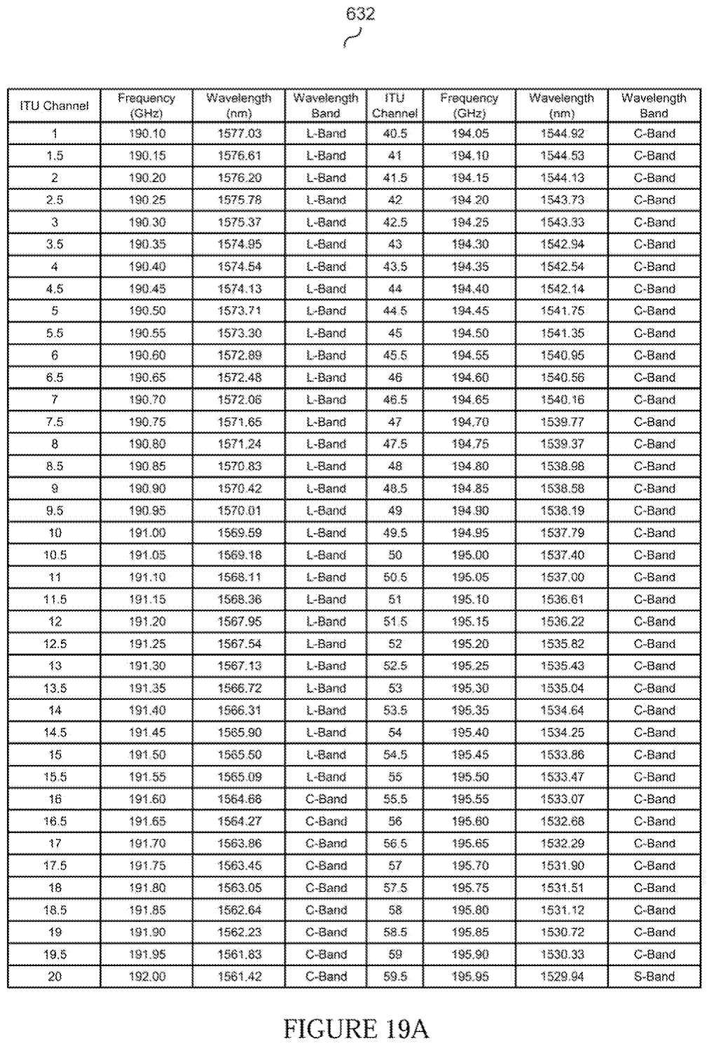

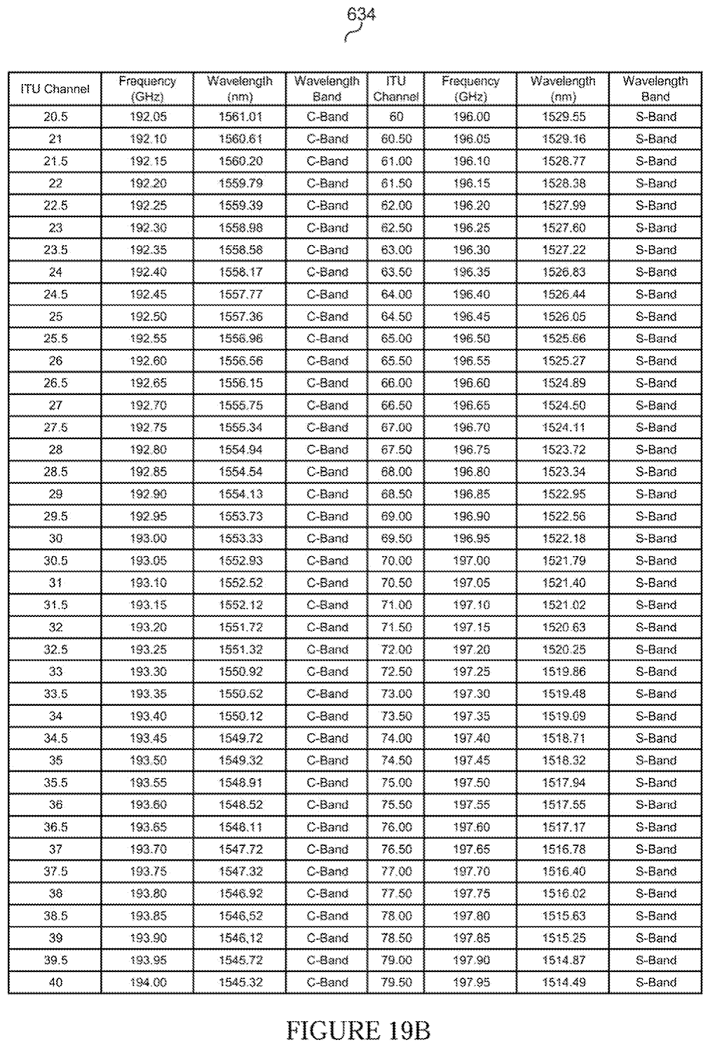

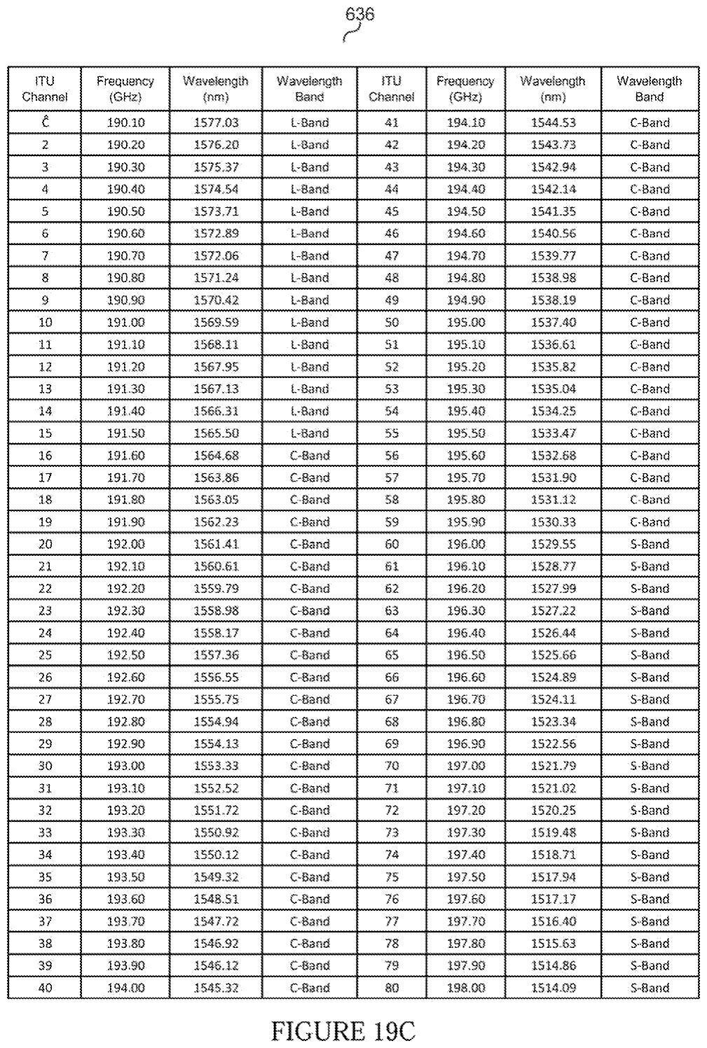

FIGS. 19a-19c illustrates DWDM 630 tables 632, 634, 636. Tables and 634 provide DWDM ITU channel, frequency, wavelength, and band for 50 GHz grid spacing. Table 636 provides DWDM ITU channel, frequency, wavelength, and band for 100 GHz grid spacing. All or a portion of the information in Tables 632, 634, 636 can be used as a communication service list for DWDM technologies. The DWDM 630 information details a are defined by the following standards or agreements.

SFF-8477, Re 1.4, Dec. 4, 2009, Specification for Tunable for XFP for ITU Frequency Grid Applications,

SFF-8690, Rev 1.4, Jan. 23, 2013, Tunable SFP+ Memory Map for ITU Frequencies, Rev 1.4

SFF-TA-1004, Rev 0.0.10 Jan. 23, 2018, Specification for Tunable QSFP+/QSFP28 Memory Map for ITU Frequencies

ITU-T-G.694.1 4, February 2012, Spectral Grids for WDM Applications: DWDM Frequency Grid

While the embodiment(s) disclosed herein are illustrative of the structure, function and operation of the exemplary method(s), circuitry, system(s), equipment and/or devices, it should be understood that various modifications may be made thereto with departing from the teachings herein. Further, the components of the method(s), circuitry, system(s), equipment an or devices disclosed herein can take any suitable form, including, any suitable hardware, software, circuitry or other components capable of adequately performing their respective intended functions, as may be known in the art. It should also be understood that all commercially available parts identified herein can be interchanged with other similar commercially available parts capable of providing the same function and results.

While the foregoing discussion presents the teachings in an exemplary fashion with respect to the disclosed method(s), circuitry, system(s), equipment, and/or devices relating to CDR circuitry for communication services, it will be apparent to those skilled in the art that the present disclosure may apply to other method(s), system(s), device(s), equipment and circuitry relating to other communication services. Further, while the foregoing has described what are considered to be the best mode and/or other examples, it is understood that various modifications may be made therein and that the subject matter disclosed herein may be implemented in various forms and examples, and that the method(s), system(s), device(s), equipment and circuitry may be applied in numerous applications, only, some of which have been described herein.

What is claimed is:

1. Circuitry for automatically aligning and locking to at least one of a communication signal bit rate or wavelength, and for re-clocking and re-generating the communication signal, the circuitry comprising:
clock data recovery (CDR) circuitry; and
microprocessor (MPU) circuitry.

2. The circuitry of claim 1, further comprising receiver circuitry and transmitter circuitry.

3. The circuitry of claim 2, further comprising port (PORT) interfaces.

4. A system for automatically aligning and locking to at least one of a communication signal bit rate and wavelength, and for re-clocking and re-generating the communication signal, the system comprising:
network equipment;
customer equipment;
a communication signal defining a bit rate and a wavelength, wherein the communication signal travels via a plurality of paths between the network equipment and the customer equipment;
clock data recovery (CDR) circuitry along the plurality of paths; and
a microprocessor (MPU) circuitry in communication with the CDR circuitry;
wherein the CDR circuitry automatically aligns and locks to at least one of a communication signal bit rate and wavelength, and re-clocks and re-generates the communication signal.

5. The system of claim 4, further comprising receiver circuitry and transmitter circuitry along the plurality of paths.

6. The system of claim 5, further comprising port (PORT) interfaces along the plurality of paths.

7. A method far provisioning clock data recovery circuitry, comprising the steps of:
automatically aligning and locking CDR circuitry to at least one of a communication signal bit rate or wavelength; and
re-clocking and re-generating a communication signal via the CDR circuitry.

8. The method of claim 7, wherein the step of automatically aligning and locking CDR circuitry includes the step of progressing through a communication services list until a communication signal bit rate or wavelength is aligned.
